(19) United States
(12) Patent Application Publication
(10) Pub. No.: US 2026/0271796 A1
(43) Pub. Date: Sep. 10, 2026

(54) SEMICONDUCTOR DEVICE

(71) Applicant: ROHM CO., LTD., Kyoto (JP)

(72) Inventor: Hiroyuki INOKUCHI, Kyoto (JP)

(73) Assignee: ROHM CO., LTD., Kyoto (JP)

(21) Appl. No.: 19/653,505

(22) Filed: Apr. 21, 2026

Related U.S. Application Data
(63) Continuation of application No. PCT/JP2024/038141, filed on Oct. 25, 2024.

(30) Foreign Application Priority Data
Nov. 1, 2023 (JP) 2023-187792

(51) Int. Cl. H10W 90/10; H10W 70/698; H10W 90/00

(52) U.S. Cl. CPC H10W 90/10; H10W 70/698; H10W 90/753

(57) ABSTRACT

A semiconductor device includes: a first chip mounted on a first die pad; a second chip mounted on a second die pad; an insulating chip mounted on the first die pad; a first bonding material for bonding the first die pad and the first chip; a second bonding material for bonding the second die pad and the second chip; and a third bonding material for bonding the first die pad and the insulating chip. The insulating chip includes: a third semiconductor substrate; a third insulating layer that is provided on the third semiconductor substrate; and a transformer that is disposed inside of the third insulating layer, and that includes a first coil and a second coil which are insulated from each other. The third semiconductor substrate is bonded to the first die pad by the third bonding material. The third bonding material is an insulating bonding material.

### CROSS-REFERENCE TO RELATED APPLICATIONS

This application is a continuation of, and claims the benefit of priority from, International Application No. PCT/JP2024/038141, filed on October 25, 2024, which claims the benefit of priority from Japanese Patent Application No. 2023-187792, filed on November 1, 2023, the entire contents of each are incorporated herein by reference.

### BACKGROUND

### 1. Field

The following description relates to a semiconductor device.

### 2. Description of Related Art

JP2018-78169A discloses a module including a controller chip, a transformer chip, and a driver chip. The controller chip and the transformer chip are disposed on a first die pad, and the driver chip is disposed on a second die pad. The transformer chip includes a substrate, and a stack of insulating layers formed on a main surface of the substrate. An upper coil and a lower coil are formed in different insulating layers of the stack.

### BRIEF DESCRIPTION OF THE DRAWINGS

FIG. 1 is a circuit diagram of a semiconductor device in accordance with a first embodiment.

FIG. 2 is a schematic plan view showing the internal structure of the semiconductor device in accordance with the first embodiment.

FIG. 3 is a schematic cross-sectional view of the semiconductor device taken along line F3-F3 shown in FIG. 2.

FIG. 4 is a perspective view of an isolator chip included in the semiconductor device shown in FIG. 2.

FIG. 5 is a schematic plan view of the isolator chip shown in FIG. 4.

FIG. 6 is a schematic plan view of first coils and an electrode structure inside the isolator chip.

FIG. 7 is a schematic plan view of second coils and an electrode structure inside the isolator chip.

FIG. 8 is a schematic cross-sectional view of the isolator chip taken along line F8-F8 shown in FIG. 5.

FIG. 9 is a graph indicating changes in the voltage at a first coil included in a comparative semiconductor device during a surge withstand capability test.

FIG. 10 is a graph indicating changes in the voltage at the first coil included in the semiconductor device in accordance with the first embodiment during a surge withstand capability test.

FIG. 11 is a circuit diagram of a semiconductor device in accordance with a second embodiment.

FIG. 12 is a schematic plan view showing the internal structure of the semiconductor device in accordance with the second embodiment.

FIG. 13 is a schematic cross-sectional view of the semiconductor device taken along line F13-F13 shown in FIG. 12.

FIG. 14 is a circuit diagram of a semiconductor device in accordance with a third embodiment.

FIG. 15 is a schematic cross-sectional view showing the internal structure of the semiconductor device in accordance with the third embodiment.

FIG. 16 is a schematic cross-sectional view of an isolator chip.

FIG. 17 is a schematic cross-sectional view of a modified semiconductor device.

FIG. 18 is a schematic cross-sectional view of another modified semiconductor device.

FIG. 19 is a schematic cross-sectional view of another modified semiconductor device.

FIG. 20 is a schematic plan view of an isolator chip included in another modified semiconductor device.

FIG. 21 is a schematic cross-sectional view of the isolator chip taken along line F21-F21 shown in FIG. 20.

FIG. 22 is a schematic cross-sectional view of another modified semiconductor device.

FIG. 23 is a schematic plan view showing the internal structure of another modified semiconductor device.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

Several embodiments of a semiconductor device according to the present disclosure will now be described with reference to the accompanying drawings. Elements in the drawings may not be drawn to scale for simplicity and clarity of illustration. In the cross-sectional drawings, hatching lines may not be shown in order to facilitate understanding. The accompanying drawings merely illustrate exemplary embodiments of the present disclosure and are not intended to limit the present disclosure.

This detailed description includes exemplary embodiments of devices, systems, and methods in accordance with the present disclosure. The present description is illustrative and is not intended to limit the embodiments of the present disclosure or application and use of the embodiments.

In this specification, the phrase “at least one of” as used in this disclosure means “one or more” of desired options. In an example, the phrase “at least one of” means “only one of two options” or “both of two options” if the number of options is two. In another example, the phrase “at least one of” means “only one of the options” or “any combination of two or more of the options” if the number of options is three or more.

In this specification, phrases such as “the dimension (thickness) of A is equal to the dimension (thickness) of B” or “A and B have the same dimension (thickness)” include a relationship in which the difference between the dimension (thickness) of A and the dimension (thickness) of B is, for example, within 10% of the dimension (thickness) of A.

### First Embodiment

### Overall Structure of Semiconductor Device

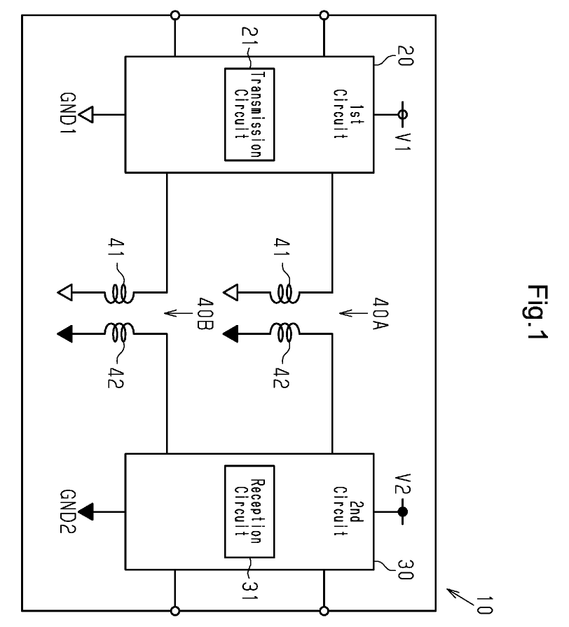

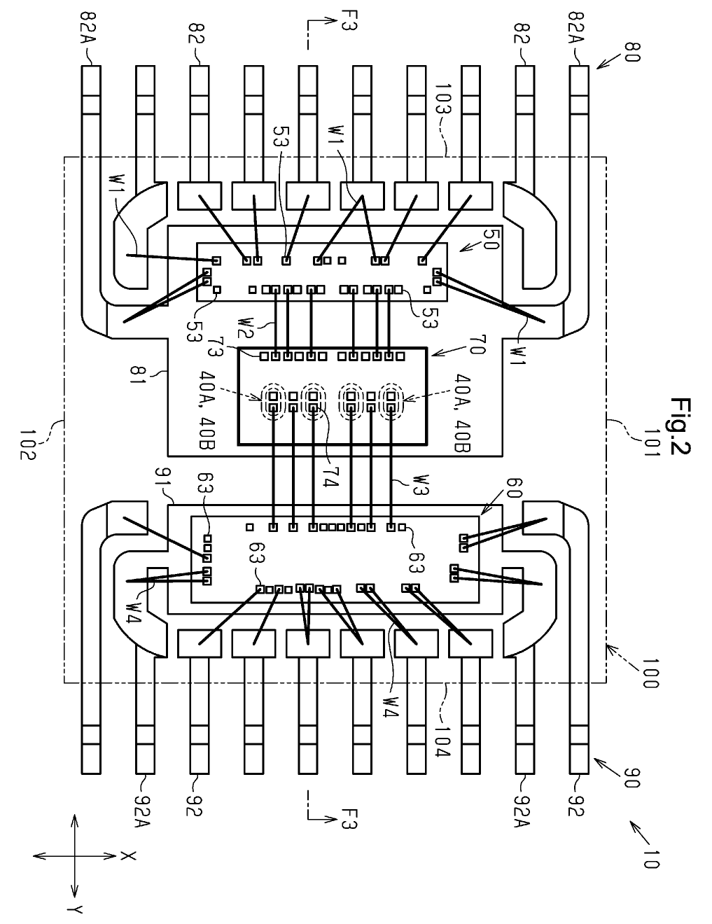

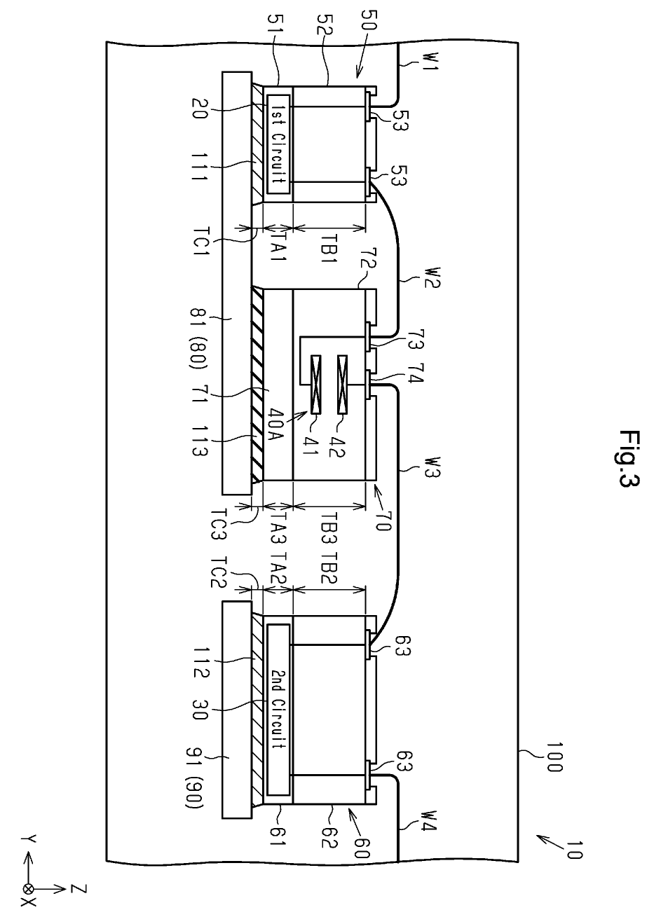

The overall structure of a semiconductor device 10 in accordance with a first embodiment will now be described with reference to FIGS. 1 to 3. FIG. 1 is a schematic circuit diagram of the semiconductor device 10 in accordance with the first embodiment. FIG. 2 is a schematic plan view showing an exemplary internal structure of the semiconductor device 10. In FIG. 2, an encapsulation resin 100 (described later) is indicated by double-dashed lines in order to reveal the internal structure of the semiconductor device 10. FIG. 3 is a schematic cross-sectional view of the semiconductor device 10 taken along line F3-F3 shown in FIG. 2.

The circuitry of the semiconductor device 10 is simplified in FIG. 1, such that the number of external terminals of the semiconductor device 10 shown in FIG. 2 is greater than the number of external terminals of the semiconductor device 10 shown in FIG. 1. The number of external terminals of the semiconductor device 10 refers to the number of external electrodes that are configured to connect the semiconductor device 10 to an electronic component located outside the semiconductor device 10.

As shown in FIG. 1, the semiconductor device 10 includes a first circuit 20, a second circuit 30, and transformers 40A and 40B. The transformers 40A and 40B electrically isolate the first circuit 20 and the second circuit 30. The transformers 40A and 40B are examples of an “isolation element”.

The first circuit 20 is configured to operate using a first voltage V1. In an example, the first circuit 20 includes a transmission circuit or a reception circuit. In the first embodiment, the first circuit 20 includes a transmission circuit 21. The transmission circuit 21 includes at least one transistor. The second circuit 30 is configured to operate using a second voltage V2. In an example, the second circuit 30 includes a transmission circuit or a reception circuit. In the first embodiment, the second circuit 30 includes a reception circuit 31. The reception circuit 31 includes at least one transistor. The first voltage V1 and the second voltage V2 may be the same or differ from each other. In an example, the second voltage V2 is equal to the first voltage V1. The semiconductor device 10 may be referred to as a digital isolator. Accordingly, the semiconductor device 10 may also be referred to as a signal transmission device that is configured to transmit a signal from the first circuit 20 to the second circuit 30. In the first embodiment, ground GND1 of the first circuit 20 and ground GND2 of the second circuit 30 are arranged independent from each other.

The transformers 40A and 40B are respectively provided for two types of signals transmitted from the first circuit 20 to the second circuit 30. These signals may be, for example, a SET signal and a RESET signal for driving a switching element. The SET signal transmits a rising edge of a control signal from a control circuit (not shown), and the RESET signal transmits a falling edge of the control signal from the control circuit. In an example, the transformer 40A is used for transmitting a SET signal, and the transformer 40B is used for transmitting a RESET signal.

The transformers 40A and 40B each include a first coil 41 and a second coil 42. The first coil 41 and the second coil 42 are electrically isolated from each other and are configured to be magnetically coupled to each other. The first coils 41 are electrically connected to the transmission circuit 21 of the first circuit 20. The second coils 42 are electrically connected to the reception circuit 31 of the second circuit 30.

The first coils 41 of the transformers 40A and 40B each have a first end electrically connected to the first circuit 20. The first coils 41 of the transformers 40A and 40B each have a second end electrically connected to the ground GND1. The second coils 42 of the transformers 40A and 40B each have a first end electrically connected to the second circuit 30. The second coils 42 of the transformers 40A and 40B each have a second end electrically connected to the ground GND2.

In response to an input signal, the transmission circuit 21 of the first circuit 20 drives, for example, the transformer 40A in a pulsed manner. The pulse signal applied to the first coil 41 of the transformer 40A is transmitted to the second coil 42 of the transformer 40A and is then input to the reception circuit 31 of the second circuit 30. Based on the received pulse signal, the reception circuit 31 outputs an output signal. In this case, the transmission circuit 21 may drive the transformer 40B in a pulsed manner.

### Internal Structure of Semiconductor Device

As shown in FIG. 2, the semiconductor device 10 includes multiple semiconductor chips that are packaged together. The semiconductor device 10 includes semiconductor chips, namely, a first chip 50, a second chip 60, and an isolator chip 70.

The package type of the semiconductor device 10 is small outline (SO). In the first embodiment, the semiconductor device 10 is a small outline package (SOP). The package type of the semiconductor device 10 may be changed. The package type is not limited to SOP and may be a quad flat no-lead package (QFN), a dual flat package (DFP), a dual in-line package (DIP), a quad flat package (QFP), a single in-line package (SIP), a small outline J-leaded package (SOJ), or any other similar package type.

The semiconductor device 10 further includes a first lead frame 80, a second lead frame 90, and the encapsulation resin 100.

The encapsulation resin 100 entirely encapsulates the first chip 50, the second chip 60, and the isolator chip 70, and partially encapsulates the first lead frame 80 and the second lead frame 90. The encapsulation resin 100 encapsulates a first die pad 81 (described later) of the first lead frame 80 and a second die pad 91 (described later) of the second lead frame 90. The encapsulation resin 100 is formed from an electrically insulating resin material. Such a resin material includes, for example, a black epoxy resin. The encapsulation resin 100 has a rectangular plate shape and has a thickness in a Z-direction. The encapsulation resin 100 includes four encapsulation side surfaces 101 to 104. More specifically, the encapsulation resin 100 includes the encapsulation side surfaces 101 and 102 serving as two end surfaces in an X-direction, and the encapsulation side surfaces 103 and 104 serving as two end surfaces in a Y-direction. The X-direction and the Y-direction are both orthogonal to the Z-direction. The X-direction and the Y-direction are orthogonal to each other as viewed in the Z-direction. The encapsulation resin 100 is rectangular as viewed in the Z-direction, with long sides extending in the X-direction and short sides extending in the Y-direction. The Y-direction is an example of a “first direction”. In the description hereafter, the term “plan view” refers to a view taken in the Z-direction. The planar shape of the encapsulation resin 100 may be changed. In an example, the encapsulation resin 100 may be rectangular in plain view, with long sides extending in the Y-direction and short sides extending in the X-direction.

The first lead frame 80 and the second lead frame 90 are both conductors formed from a material containing, for example, copper (Cu), iron (Fe), aluminum (Al), or the like. The lead frames 80 and 90 extend from the inside of the encapsulation resin 100 to the outside.

The first lead frame 80 includes the first die pad 81 disposed inside the encapsulation resin 100 and first leads 82 extending from the inside of the encapsulation resin 100 to the outside. The first leads 82 serve as external terminals configured to electrically connect the semiconductor device 10 to an external electronic device. The first leads 82 include a pair of first leads 82A that are connected to the first die pad 81. The two first leads 82A are integrated with the first die pad 81.

The first chip 50 is mounted on the first die pad 81. In plain view, the first die pad 81 is disposed so that the center of the first die pad 81 in the Y-direction is located closer to the encapsulation side surface 103 than the center of the encapsulation resin 100 in the Y-direction is. In the first embodiment, the first die pad 81 is not exposed from the encapsulation resin 100. In an example, the first die pad 81 is rectangular in plain view, with long sides extending in the X-direction and short sides extending in the Y-direction.

The first leads 82 are arranged next to and spaced apart from each other in the X-direction. The outermost ones of the first leads 82 in the X-direction are integrated with the first die pad 81. The remaining first leads 82 are separated from the first die pad 81 in the Y-direction. Each first lead 82 partially projects out of the encapsulation resin 100 from the encapsulation side surface 103.

The second lead frame 90 includes the second die pad 91 disposed inside the encapsulation resin 100, and second leads 92 extending from the inside of the encapsulation resin 100 to the outside. The second leads 92 serve as external terminals configured to electrically connect the semiconductor device 10 to an external electronic device. The second leads 92 include a pair of second leads 92A that are connected to the second die pad 91. The two second leads 92A are integrated with the second die pad 91.

The second chip 60 is mounted on the second die pad 91. In plain view, the second die pad 91 is located closer to the encapsulation side surface 104 than the first die pad 81 is in the Y-direction. That is, the first die pad 81 and the second die pad 91 are spaced apart from each other in the Y-direction. Accordingly, the Y-direction may be referred to as an arrangement direction of the two die pads 81 and 91. Furthermore, the first chip 50 and the second chip 60 are spaced apart from each other in the Y-direction. The first die pad 81 and the second die pad 91 are insulated from each other. In the first embodiment, the second die pad 91 is not exposed from the encapsulation resin 100. In an example, the second die pad 91 is rectangular in plain view, with long sides extending in the X-direction and short sides extending in the Y-direction.

The second leads 92 are arranged next to and spaced apart from each other in the X-direction. The second outermost ones of the second leads 92 in the X-direction are integrated with the second die pad 91. The remaining second leads 92 are each separated from the second die pad 91 in the X-direction or the Y-direction. Each second lead 92 partially projects out of the encapsulation resin 100 from the encapsulation side surface 104.

In the first embodiment, the number of first leads 82 is equal to the number of second leads 92. As shown in FIG. 2, in plain view, the first leads 82 and the second leads 92 are both arranged in a direction (X-direction) orthogonal to the arrangement direction (Y-direction) of the first die pad 81 and the second die pad 91. The number of first leads 82 and the number of second leads 92 may be changed. In an example, the first leads 82 and the second leads 92 may be different in quantity.

In the first embodiment, the first die pad 81 is supported by the two first leads 82 that are integrated with the first die pad 81. The second die pad 91 is supported by the two second leads 92 that are integrated with the second die pad 91. Accordingly, the die pads 81 and 91 are not provided with suspension leads exposed from the encapsulation side surfaces 101 and 102. This allows the first lead frame 80 and the second lead frame 90 to be spaced apart from each other by a relatively long insulation distance (creepage distance).

The first chip 50, mounted on the first die pad 81, is a semiconductor chip that includes the first circuit 20 shown in FIG. 1. In plain view, the first chip 50 has a rectangular shape with short sides and long sides. The first chip 50 is mounted on the first die pad 81, so that the long sides extend in the X-direction and the short sides extend in the Y-direction in plain view.

As shown in FIG. 3, the first chip 50 includes a first semiconductor substrate 51, a first insulating layer 52, and electrode pads 53. The first semiconductor substrate 51 is composed of, for example, a material containing silicon (Si). In an example, the first semiconductor substrate 51 is a Si substrate. The first insulating layer 52 is formed on the first semiconductor substrate 51. The first insulating layer 52 includes, for example, at least one of a silicon oxide film (SiO₂) and a silicon nitride film (SiN). The first insulating layer 52 includes an interconnect that electrically connects the first semiconductor substrate 51 and the electrode pads 53. The electrode pads 53 are arranged on the first insulating layer 52.

The first chip 50 is bonded to the first die pad 81 by a first bonding material 111. The first bonding material 111 is disposed between the first die pad 81 and the first chip 50. The first bonding material 111 bonds the first semiconductor substrate 51 and the first die pad 81. In the first embodiment, the first bonding material 111 is a conductive bonding material. The conductive bonding material is, for example, a solder paste, a silver (Ag) paste, or the like.

As shown in FIG. 2, the second chip 60, mounted on the second die pad 91, is a semiconductor chip that includes the second circuit 30 shown in FIG. 1. In plain view, the second chip 60 has a rectangular shape with short sides and long sides. The second chip 60 is mounted on the second die pad 91, so that the long sides extend in the X-direction and the short sides extend in the Y-direction in plain view.

As shown in FIG. 3, the second chip 60 includes a second semiconductor substrate 61, a second insulating layer 62, and electrode pads 63. The second semiconductor substrate 61 is composed of, for example, a material containing Si. In an example, the second semiconductor substrate 61 is a Si substrate. The second insulating layer 62 is formed on the second semiconductor substrate 61. The second insulating layer 62 includes, for example, at least one of a silicon oxide film and a silicon nitride film. The second insulating layer 62 includes an interconnect that electrically connects the second semiconductor substrate 61 and the electrode pads 63. The electrode pads 63 are arranged on the second insulating layer 62.

The second chip 60 is bonded to the second die pad 91 by a second bonding material 112. The second bonding material 112 is disposed between the second die pad 91 and the second chip 60. The second bonding material 112 bonds the second semiconductor substrate 61 and the second die pad 91. In the first embodiment, the second bonding material 112 is a conductive bonding material. The conductive bonding material is, for example, a solder paste, an Ag paste, or the like.

As shown in FIG. 2, in the first embodiment, the isolator chip 70 is mounted on the first die pad 81. The isolator chip 70 is disposed on the first die pad 81 at a position that is located closer to the second chip 60 than the first chip 50 is. That is, the isolator chip 70 is located between the first chip 50 and the second chip 60 in the Y-direction. The distance from the second chip 60 to the isolator chip 70 in the Y-direction is greater than the distance from the first chip 50 to the isolator chip 70 in the Y-direction. The isolator chip 70 is connected between the first chip 50 and the second chip 60.

The isolator chip 70 is a semiconductor chip including the transformers 40A and 40B. In plain view, the isolator chip 70 has a rectangular shape with short sides and long sides. The isolator chip 70 is mounted on the first die pad 81, so that the long sides extend in the X-direction and the short sides extend in the Y-direction in plain view.

As shown in FIG. 3, the isolator chip 70 includes a third semiconductor substrate 71, a third insulating layer 72, and electrode pads 73 and 74. The third insulating layer 72 is an example of an “insulator”.

The third semiconductor substrate 71 is composed of, for example, a material containing Si. In an example, the third semiconductor substrate 71 is a Si substrate. The third insulating layer 72 is disposed on the third semiconductor substrate 71. The third insulating layer 72 includes the first coils 41 and the second coils 42 of the transformers 40A and 40B, which are shown in FIG. 1. The electrode pads 73 and 74 are disposed on the third insulating layer 72.

The isolator chip 70 is bonded to the first die pad 81 by a third bonding material 113. The third bonding material 113 is disposed between the first die pad 81 and the isolator chip 70. The third bonding material 113 bonds the third semiconductor substrate 71 and the first die pad 81. The third bonding material 113 is an insulative bonding material. The insulative bonding material is, for example, an insulation material containing an epoxy resin.

In the first embodiment, the first chip 50, the second chip 60, and the isolator chip 70 have the following relationship in terms of their thicknesses. A thickness TA3 of the third semiconductor substrate 71 is equal to a thickness TA1 of the first semiconductor substrate 51. The thickness TA3 of the third semiconductor substrate 71 is equal to a thickness TA2 of the second semiconductor substrate 61. A thickness TB3 of the third insulating layer 72 is equal to a thickness TB1 of the first insulating layer 52. The thickness TB3 of the third insulating layer 72 is equal to a thickness TB2 of the second insulating layer 62. A thickness TC3 of the third bonding material 113 is equal to a thickness TC1 of the first bonding material 111. The thickness TC3 of the third bonding material 113 is equal to a thickness TC2 of the second bonding material 112.

In this manner, in the first embodiment, the first chip 50, the second chip 60, and the isolator chip 70 have the same height. Accordingly, the electrode pads 53 of the first chip 50, the electrode pads 63 of the second chip 60, and the electrode pads 73 and 74 of the isolator chip 70 are located at the same position in the Z-direction.

As shown in FIGS. 2 and 3, wires W1 to W4 are connected to the first chip 50, the isolator chip 70, and the second chip 60. The wires W1 to W4 are bonding wires formed by a wire bonding device. The wires W1 to W4 are composed of, for example, a conductor containing gold (Au), Al, Cu, or the like.

As shown in FIG. 2, the first chip 50 is electrically connected to the first lead frame 80 by the wires W1. More specifically, the electrode pads 53 of the first chip 50 are separately connected to the first leads 82 by the wires W1. Some of the wires W1 are separately connected to the two first leads 82 that are integrated with the first die pad 81. In the first embodiment, the two first leads 82A that are integrated with the first die pad 81 define ground terminals. Accordingly, the first die pad 81 has the same potential as the ground GND1 (refer to FIG. 1) of the first circuit 20.

The second chip 60 is electrically connected to the second lead frame 90 by the wires W4. More specifically, the electrode pads 63 of the second chip 60 are separately connected to the second leads 92 by the wires W4. Some of the wires W4 are separately connected to the two second leads 92A that are integrated with the second die pad 91. In the first embodiment, the two second leads 92A that are integrated with the second die pad 91 define ground terminals. Accordingly, the second die pad 91 has the same potential as the ground GND2 (refer to FIG. 1) of the second circuit 30.

The isolator chip 70 is electrically connected to the first chip 50 by the wires W2. The isolator chip 70 is electrically connected to the second chip 60 by the wires W3. More specifically, the electrode pads 73 of the isolator chip 70 are separately connected to the electrode pads 53 of the first chip 50 by the wires W2. Further, the electrode pads 74 of the isolator chip 70 are separately connected to the electrode pads 63 of the second chip 60 by the wires W3.

The first coils 41 of the transformers 40A and 40B are electrically connected to the ground GND1 of the first circuit 20 via the wires W2, the first chip 50, and the like. The second coils 42 of the transformers 40A and 40B are electrically connected to the ground GND2 of the second circuit 30 via the wires W3, the second chip 60, and the like.

The semiconductor substrates 51, 61, and 71, shown in FIG. 3, may each be a wide-bandgap semiconductor or a compound semiconductor, instead of the Si substrate. The wide-bandgap semiconductor is a semiconductor substrate having a bandgap of 2.0eV or more. The wide-bandgap semiconductor may contain silicon carbide (SiC), gallium nitride (GaN), gallium oxide (Ga₂O₃), or the like. The compound semiconductor may be a III-V compound semiconductor. The compound semiconductor may contain at least one of aluminum nitride (AlN), indium nitride (InN), GaN, and gallium arsenide (GaAs).

### Structure of Isolator Chip

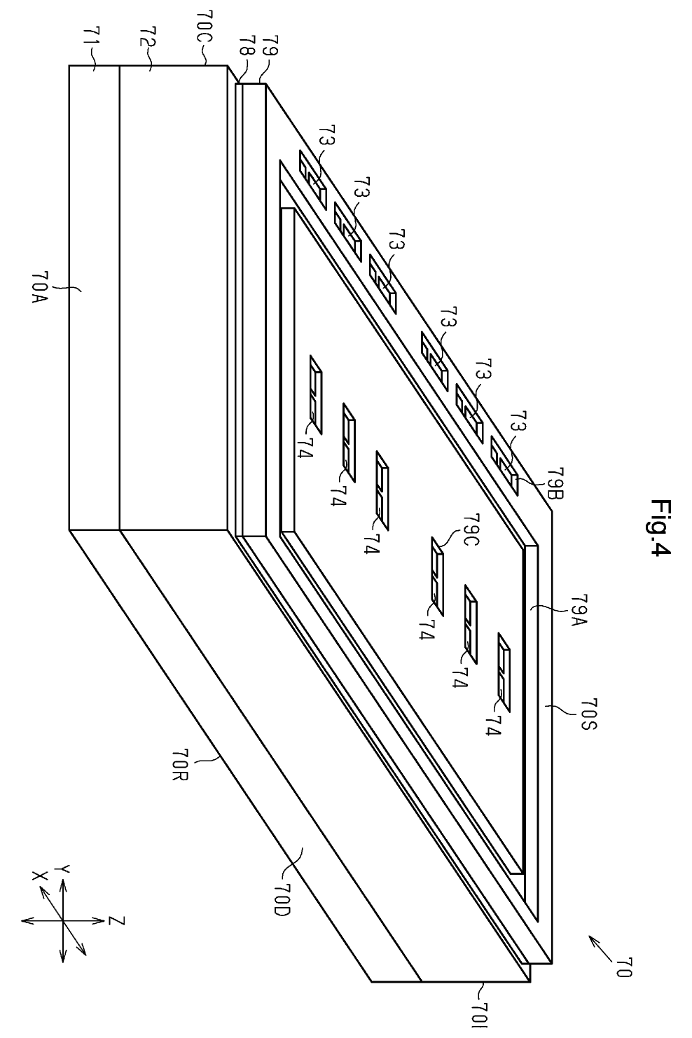

An exemplary structure of the isolator chip 70 will now be described with reference to FIGS. 4 to 8.

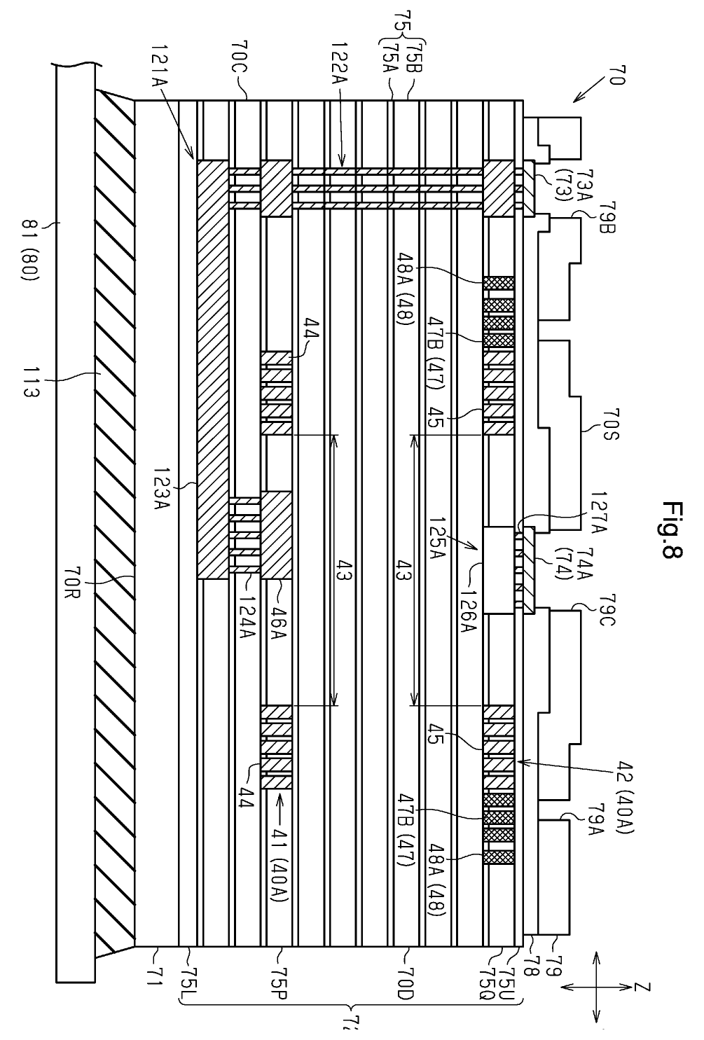

In the description hereafter, a direction extending from the third semiconductor substrate 71 toward the third insulating layer 72 of the isolator chip 70, shown in FIG. 8, will be referred to as an upward direction, and a direction extending from the third insulating layer 72 toward the third semiconductor substrate 71 will be referred to as a downward direction.

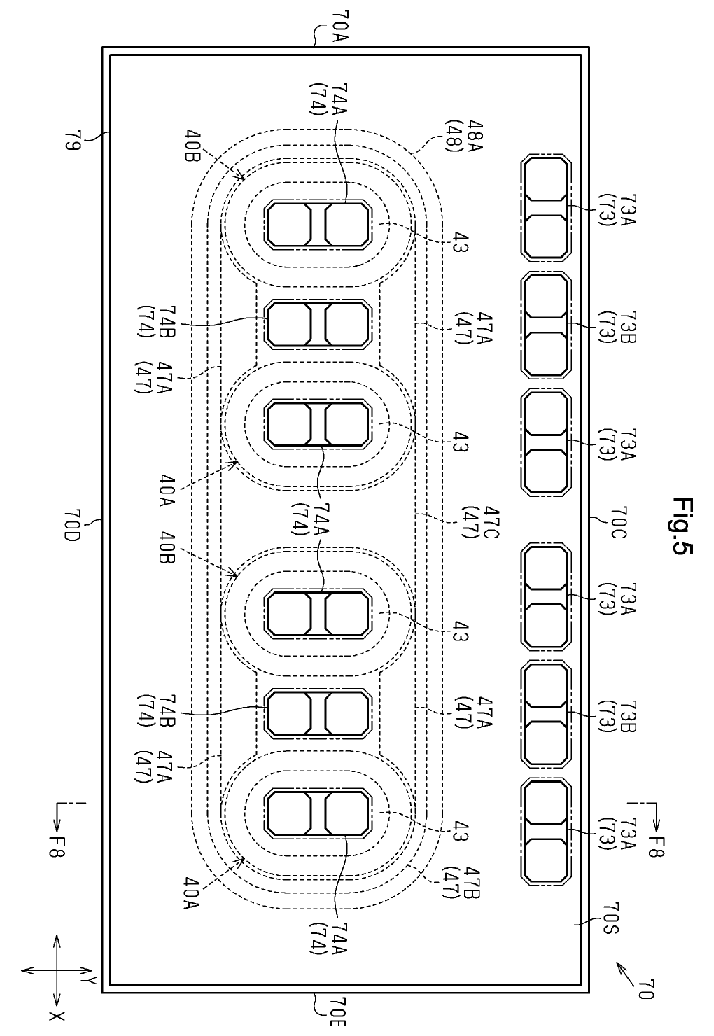

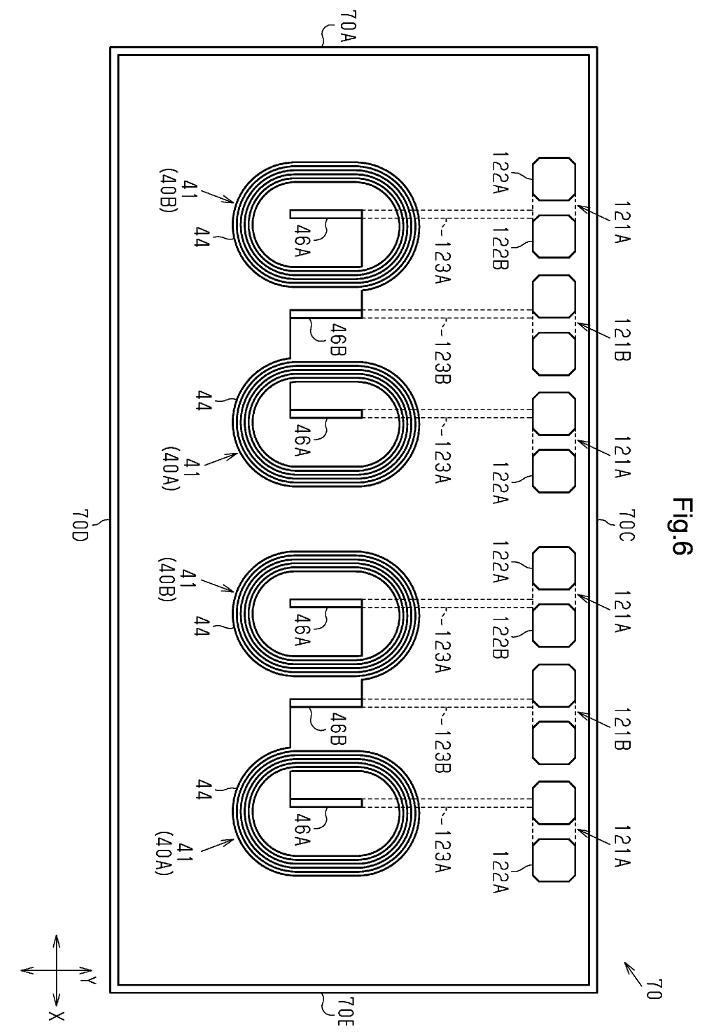

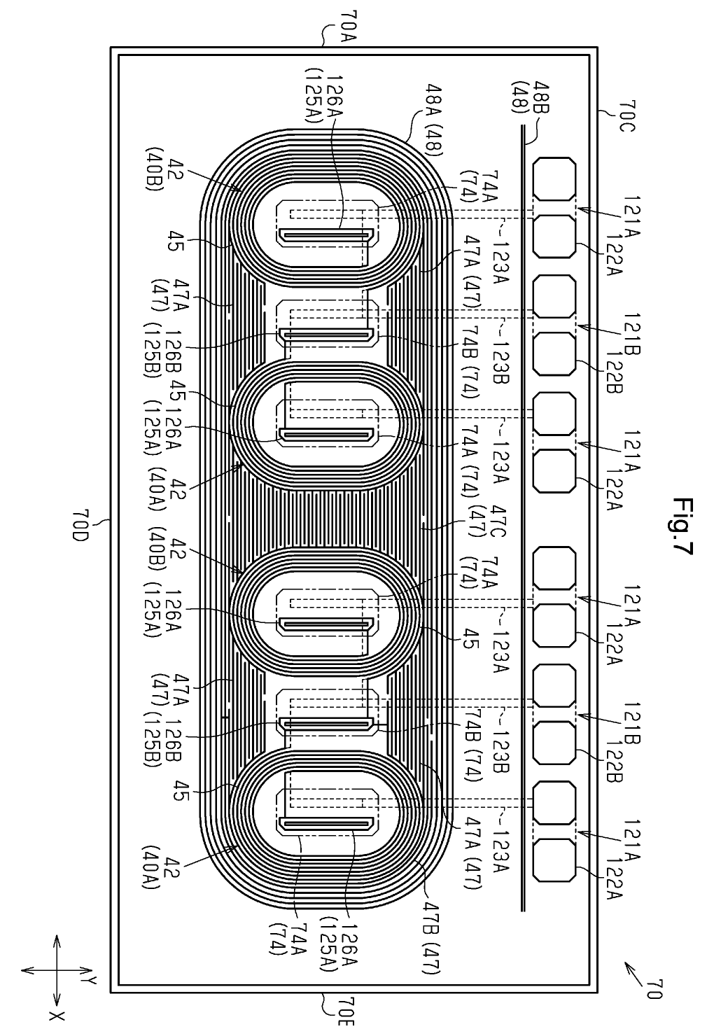

FIGS. 4 and 5 show the external appearance of the isolator chip 70. FIG. 4 is a perspective view of the isolator chip 70, and FIG. 5 is a plan view of the isolator chip 70. In FIG. 5, for illustrative purposes, double-dashed lines indicate a passivation film 78 (described later), and broken lines indicate the transformers 40A and 40B and a floating dummy wiring 48 (described later). In addition, FIG. 5 does not show a resin layer 79 (described later) including a separation trench 79A, a first resin opening 79B, and a second resin opening 79C, which are shown in FIG. 4. FIG. 6 is a cross-sectional view of the isolator chip 70 taken along an XY-plane at a position where the first coils 41 are located in the Z-direction. FIG. 6 shows the connection relationship of the first coils 41. FIG. 7 is a cross-sectional view of the isolator chip 70 taken along an XY-plane at a position where the second coils 42 are located in the Z-direction. FIG. 7 shows the connection relationship of the second coils 42. FIG. 8 is a cross-sectional view of the isolator chip 70, the third bonding material 113, and the first die pad 81, taken along line F8-F8 shown in FIG. 5.

As shown in FIG. 4, the isolator chip 70 includes a chip upper surface 70S, a chip lower surface 70R, and first to fourth chip side surfaces 70A to 70D. The chip upper surface 70S and the chip lower surface 70R face away from each other in the Z-direction. The first to fourth chip side surfaces 70A to 70D are four chip side surfaces connecting the chip upper surface 70S and the chip lower surface 70R. The chip lower surface 70R is defined by the third semiconductor substrate 71. The electrode pads 73 and 74 are exposed from the chip upper surface 70S. The first chip side surface 70A and the second chip side surface 70B define two end surfaces of the isolator chip 70 in the X-direction. The third chip side surface 70C and the fourth chip side surface 70D define two end surfaces of the isolator chip 70 in the Y-direction.

As shown in FIG. 5, the isolator chip 70 includes two pairs of transformers 40A and 40B. More specifically, the isolator chip 70 is a semiconductor chip that integrates the two pairs of transformers 40A and 40B. The isolator chip 70 is separate from the first chip 50 and the second chip 60, which are shown in FIG. 3. The two pairs of the transformers 40A and 40B are located at the same position in the Y-direction and are spaced apart from each other in the X-direction. In the two pairs of the transformers 40A and 40B, the transformer 40A and the transformer 40B are alternately arranged in the X-direction.

In plain view, the transformers 40A and 40B are disposed at a central part of the isolator chip 70 in the Y-direction. In an example, the electrode pads 73 and 74 are arranged at positions that do not overlap the transformers 40A and 40B in plain view. The electrode pads 73 and 74 are electrically connected to the transformers 40A and 40B. The electrode pads 73 and 74 are composed of a material containing one or more selected from titanium (Ti), titanium nitride (TiN), Au, Ag, Cu, Al, and tungsten (W). The electrode pads 73 and 74 are composed of, for example, a material containing Al.

In plan view, the electrode pads 73 are located closer to the third chip side surface 70C than the transformers 40A and 40B are. In other words, in plain view, the electrode pads 73 are located between the transformers 40A and 40B and the third chip side surface 70C in the Y-direction. Four electrode pads 73 are aligned with the two transformers 40A and the two transformers 40B, respectively, in the X-direction, and two electrode pads 73 are each located at a position corresponding to an area between the transformer 40A and the transformer 40B in the X-direction.

In plain view, each electrode pad 73 is elongated in the X-direction in which the electrode pads 73 are arranged. In an example, the electrode pad 73 has a rectangular shape, with long sides extending in the X-direction and short sides extending in the Y-direction.

The electrode pads 73 include first pads 73A each electrically connected to the transformer 40A or the transformer 40B, and second pads 73B each electrically connected to both the transformer 40A and the transformer 40B. The second pads 73B serve as common pads for the transformers 40A and 40B. The first pads 73A and the second pads 73B are located at the same position in the Y-direction and are spaced apart from each other in the X-direction. As viewed in the Y-direction, the first pads 73A are located at positions that overlap the transformers 40A and 40B, respectively. As viewed in the Y-direction, the second pads 73B are each located at a position that overlaps an area between the transformer 40A and the transformer 40B in the X-direction. In this manner, each second pad 73B is disposed between two first pads 73A in the X-direction.

As viewed in the X-direction, the electrode pads 74 are located at positions that overlap the transformers 40A and 40B. In plain view, each electrode pad 74 is elongated in the Y-direction orthogonal to the direction in which the electrode pads 74 are arranged. In an example, the electrode pad 74 has a rectangular shape, with long sides extending in the Y-direction and short sides extending in the X-direction.

The electrode pads 74 include first pads 74A each electrically connected to the transformer 40A or the transformer 40B, and second pads 74B each electrically connected to both the transformer 40A and the transformer 40B. The second pads 74B serve as common pads for the transformers 40A and 40B. The first pads 74A and the second pads 74B are located at the same position in the Y-direction and are spaced apart from each other in the X-direction. In plain view, each first pad 74A is located in an inner region 43 of a corresponding one of the transformers 40A and 40B. The second pads 74B are located outside the transformers 40A and 40B. Each second pad 74B is located between the transformer 40A and the transformer 40B in the X-direction.

The two pairs of the transformers 40A and 40B have the same structure. Further, the transformer 40A and the transformer 40B have the same structure. Hence, the structure of the transformer 40A will be described in detail, and the structure of the transformer 40B will not be described in detail.

As shown in FIG. 8, the transformer 40A is disposed in the third insulating layer 72. The transformer 40A is disposed inside the third insulating layer 72. In other words, the transformer 40A is embedded in the third insulating layer 72. The third insulating layer 72 includes multiple insulating films 75 stacked on the third semiconductor substrate 71 in the Z-direction. That is, the Z-direction may be referred to as the thickness-wise direction of the third insulating layer 72. The Z-direction may also be referred to as the stacking direction of the insulating films 75.

The insulating films 75 include a first insulating film 75A, and a second insulating film 75B formed on the first insulating film 75A. The first insulating film 75A is a thin film, such as an etching stopper layer. The first insulating film 75A is composed of a material containing SiN, SiC, silicon carbon nitride (SiCN), or the like. In the first embodiment, the first insulating film 75A is composed of a material containing SiN. The second insulating film 75B is, for example, an interlayer insulating film. The second insulating film 75B is composed of a material containing SiO₂. The second insulating film 75B is thicker than the first insulating film 75A. The first insulating film 75A may have a thickness that is greater than or equal to 100nm and less than 1000nm. The second insulating film 75B may have a thickness that is between 1000nm to 3000nm, inclusive. In an example, the thickness of the first insulating film 75A is approximately 300nm, and the thickness of the second insulating film 75B is approximately 2000nm.

The third insulating layer 72 includes an uppermost insulating film 75U, and a lowermost insulating film 75L that is in contact with the third semiconductor substrate 71. The lowermost insulating film 75L and the uppermost insulating film 75U are each formed by the second insulating film 75B. In an example, the lowermost insulating film 75L and the uppermost insulating film 75U are both thinner than another second insulating film 75B. The lowermost insulating film 75L and the uppermost insulating film 75U are both as thick as and thicker than the first insulating film 75A.

The thickness of the lowermost insulating film 75L and the thickness of the uppermost insulating film 75U may be changed. In an example, the lowermost insulating film 75L and the uppermost insulating film 75U may both be as thick as or thicker than the second insulating film 75B. The lowermost insulating film 75L and the uppermost insulating film 75U may both be as thick as or thicker than the insulating film 75, which is formed by the first insulating film 75A and the second insulating film 75B.

As shown in FIG. 6, the first coils 41 of the transformers 40A and 40B are each formed by a first coil wiring 44. The first coil wiring 44 has an elliptical spiral shape in plain view. The first coil wiring 44 is composed of a material containing one or more selected from Ti, TiN, Au, Ag, Cu, Al, and W. In an example, the first coil wiring 44 is composed of a material containing Cu. The first coil 41 is an example of a “first conductive layer”.

An inner end wiring 46A is disposed at an inner side of the first coil wiring 44. An outer end wiring 46B is disposed at an outer side of the first coil wiring 44. The first coil wiring 44 has an inner end electrically connected to the inner end wiring 46A. Further, the first coil wiring 44 has an outer end electrically connected to the outer end wiring 46B. In an example, the inner end wiring 46A is located at a position offset from the center of the first coil 41 in the X-direction. In an example, the outer end wiring 46B is located at a position offset, toward the transformer 40B, from the center position between the first coil 41 of the transformer 40A and the first coil 41 of the transformer 40B in the X-direction.

The inner end wiring 46A and the outer end wiring 46B are composed of a material containing one or more selected from Ti, TiN, Au, Ag, Cu, Al, and W. In an example, the inner end wiring 46A and the outer end wiring 46B are composed of a material containing Cu. That is, the inner end wiring 46A and the outer end wiring 46B may be composed of the same material as the first coil wiring 44. The outer end wiring 46B serves as a common end wiring for the first coils 41 of the transformers 40A and 40B. Alternatively, an outer end wiring may be arranged for each of the first coils 41 of the transformers 40A and 40B.

As shown in FIGS. 6 and 8, the inner end wiring 46A is connected to the first pad 73A by an interconnect 121A. The interconnect 121A is composed of a material containing one or more selected from Ti, TiN, Au, Ag, Cu, Al, and W. In an example, the interconnect 121A is composed of a material containing Cu.

As shown in FIG. 8, the interconnect 121A includes a first interconnect portion 122A extending through multiple insulating films 75 in the Z-direction, and a second interconnect portion 123A extending in the Y-direction.

The first interconnect portion 122A is located at a position that overlaps the first pad 73A in plain view. The first interconnect portion 122A is connected to the first pad 73A. In an example, the first interconnect portion 122A extends through multiple insulating films 75 from the uppermost insulating film 75U to the insulating film 75 that is the second film above the lowermost insulating film 75L. The first interconnect portion 122A includes flat wiring parts and multiple vias. Two wiring parts are respectively arranged in insulating films 75P and 75Q, in which the coils 41 and 42 are disposed. The vias extend in the Z-direction, between the two wiring parts, between the upper wiring part and the first pad 73A, and between the lower wiring part and the second interconnect portion 123A.

The second interconnect portion 123A is located closer to the third semiconductor substrate 71 than the first interconnect portion 122A is. The second interconnect portion 123A is located closer to the third semiconductor substrate 71 than the first coil 41 is. In the first embodiment, the second interconnect portion 123A is arranged in the insulating film 75 that is located immediately above the lowermost insulating film 75L. The second interconnect portion 123A is connected to the first interconnect portion 122A. The second interconnect portion 123A has an end part located opposite to the first interconnect portion 122A in the Y-direction. In plain view, this end part overlaps the inner end wiring 46A, which is connected to the first coil 41 of the transformer 40A. The second interconnect portion 123A is connected to the inner end wiring 46A by vias 124A.

As shown in FIG. 6, the outer end wiring 46B is electrically connected to the second pad 73B (refer to FIG. 5) by an interconnect 121B. The interconnect 121B is composed of a material containing one or more selected from Ti, TiN, Au, Ag, Cu, Al, and W. In an example, the interconnect 121B is composed of a material containing Cu. That is, the interconnect 121B may be composed of the same material as the interconnect 121A. In the same manner as the interconnect 121A, the interconnect 121B includes a first interconnect portion 122B, a second interconnect portion 123B, and multiple vias (not shown). The first interconnect portion 122B, the second interconnect portion 123B, and the vias have the same structures as the first interconnect portion 122A, the second interconnect portion 123A, and the vias 124A of the interconnect 121A, which are shown in FIG. 8.

As shown in FIG. 7, the second coils 42 of the transformers 40A and 40B each include a second coil wiring 45. The second coil wiring 45 has an elliptical spiral shape in plain view. The second coil wiring 45 is composed of a material containing one or more selected from Ti, TiN, Au, Ag, Cu, Al, and W. The second coil 42 is an example of a “second conductive layer”.

In the first embodiment, in plain view, the second coil wiring 45 has the same wiring direction as that of the first coil wiring 44 shown in FIG. 6. Further, the second coil wiring 45 has the same number of winding turns as that of the first coil wiring 44. Such relationships of the first coil wiring 44 and the second coil wiring 45, related to the number of winding turns and the winding direction, may be changed.

The second coil wiring 45 has an inner end electrically connected to the first pad 74A by an interconnect 125A. Further, the second coil wiring 45 has an outer end electrically connected to the second pad 74B by an interconnect 125B.

The interconnect 125A includes an inner end wiring 126A and multiple vias 127A (refer to FIG. 8). In an example, the inner end wiring 126A is located at a position offset from the center of the second coil 42 in the X-direction. In plain view, the inner end wiring 126A is located at a position offset from the inner end wiring 46A (refer to FIG. 8) in the X-direction. The inner end wiring 126A is located at a position that overlaps the first pad 74A in plain view. The vias 127A connect the inner end wiring 126A and the first pad 74A.

The interconnect 125B includes an outer end wiring 126B and multiple vias (not shown). In an example, the outer end wiring 126B is located at a position offset, toward the transformer 40A, from the center position between the second coil 42 of the transformer 40A and the second coil 42 of the transformer 40B in the X-direction. In plain view, the outer end wiring 126B is located at a position offset from the outer end wiring 46B (refer to FIG. 6) in the X-direction. The outer end wiring 126B is located at a position that overlaps the second pad 74B in plain view. The vias connect the outer end wiring 126B and the second pad 74B.

As shown in FIG. 8, the first coil 41 and the second coil 42 of the transformer 40A face each other in the Z-direction with one or more insulating films 75 located in between. In the first embodiment, the first coil 41 and the second coil 42 face each other in the Z-direction with multiple insulating films 75 located in between. The first coil 41 and the second coil 42 of the transformer 40B (refer to FIG. 7) have the same structure as the transformer 40A.

The first coil 41 is formed as a conductive layer embedded in the insulating film 75P. More specifically, the insulating film 75P includes a first coil groove that extends through both the first insulating film 75A and the second insulating film 75B in the Z-direction. The first coil 41, or a conductive layer, is embedded in the first coil groove of the insulating film 75P. The first coil 41 is covered by the insulating film 75P, and the insulating films 75 located next to the insulating film 75P in the Z-direction. That is, the first coil 41 is embedded in the third insulating layer 72. In other words, the first coil wiring 44 is formed by embedding a conductive layer in the first coil groove.

The second coil 42 is formed as a conductive layer embedded in the insulating film 75Q. More specifically, the insulating film 75Q includes a second coil groove that extends through both the first insulating film 75A and the second insulating film 75B in the Z-direction. The second coil 42, or a conductive layer, is embedded in the second coil groove of the insulating film 75Q. The second coil 42 is covered by the insulating film 75Q, and the insulating films 75 located next to the insulating film 75Q in the Z-direction. That is, the second coil 42 is embedded in the third insulating layer 72. In other words, the second coil wiring 45 is formed by embedding a conductive layer in the second coil groove.

The second coil 42 is located farther away from the third semiconductor substrate 71 than the first coil 41 is in the Z-direction. In other words, the second coil 42 is located upward from the first coil 41. In the first embodiment, the distance from the second coil 42 to the first coil 41 in the Z-direction is greater than the distance from the first coil 41 to the third semiconductor substrate 71 in the Z-direction.

As shown in FIGS. 5 and 7, the isolator chip 70 includes an outer dummy wiring 47. The outer dummy wiring 47 is a wiring pattern configured to not allow a current flow into the second coil wiring 45 of the second coil 42. The outer dummy wiring 47 is composed of a material containing one or more selected from Ti, TiN, Au, Ag, Cu, Al, and W. In an example, the outer dummy wiring 47 is composed of a material containing Cu. That is, the outer dummy wiring 47 may be composed of the same material as the second coil wiring 45.

In the first embodiment, the outer dummy wiring 47 includes a first dummy wiring portion 47A, a second dummy wiring portion 47B, and a third dummy wiring portion 47C.

In plain view, two first dummy wiring portions 47A are formed between the second coil wiring 45 of the transformer 40A and the second coil wiring 45 of the transformer 40B in the X-direction. The two first dummy wiring portions 47A are spaced apart from each other in the Y-direction. In plain view, the first dummy wiring portions 47A avoid the second pad 74B. The third dummy wiring portion 47C extends between the two pairs of the transformers 40A and 40B in the X-direction in plain view.

The first dummy wiring portion 47A and the third dummy wiring portion 47C are patterned differently from the second coil wiring 45. The first dummy wiring portion 47A and the third dummy wiring portion 47C are formed by multiple wires. The wires of the first dummy wiring portion 47A and the third dummy wiring portion 47C have the same wiring width and wiring interval as, for example, those of the second coil wiring 45. That is, the first dummy wiring portion 47A and the third dummy wiring portion 47C have the same density (wiring density) as that of the second coil wiring 45. The first dummy wiring portion 47A and the third dummy wiring portion 47C may have a different density from that of the second coil wiring 45. The first dummy wiring portion 47A and the third dummy wiring portion 47C may have different densities.

As shown in FIG. 7, the first dummy wiring portion 47A and the third dummy wiring portion 47C each include a first slit formed in the Y-direction. Accordingly, the first dummy wiring portion 47A forms an open loop having the first slit. The first slit avoids formation of a current loop in the first dummy wiring portion 47A.

The first dummy wiring portion 47A and the third dummy wiring portion 47C are electrically connected to the second pad 74B. Accordingly, the first dummy wiring portion 47A and the third dummy wiring portion 47C have the same potential as the second coil 42. Therefore, when a second reference potential at the second coil 42 changes, the voltages at the first dummy wiring portion 47A and the third dummy wiring portion 47C may become higher than the voltage at the first coil 41 in the same manner as the second coil 42.

In plain view, the second dummy wiring portion 47B surrounds the second coil 42, the first dummy wiring portion 47A, and the third dummy wiring portion 47C. The second dummy wiring portion 47B is electrically connected to the first dummy wiring portion 47A.

In plain view, the second dummy wiring portion 47B is formed by multiple wires surrounding the second coil 42, the first dummy wiring portion 47A, and the third dummy wiring portion 47C. The wires of the second dummy wiring portion 47B have the same wiring width and wiring interval as, for example, those of the second coil wiring 45. That is, the second dummy wiring portion 47B has the same density (wiring density) as that of the second coil wiring 45. The second dummy wiring portion 47B and the second coil wiring 45 may have different densities.

The second dummy wiring portion 47B includes a second slit formed in the Y-direction. Accordingly, the second dummy wiring portion 47B forms an open loop having the second slit. The second slit avoids formation of a current loop in the second dummy wiring portion 47B.

The isolator chip 70 includes the floating dummy wiring 48. The floating dummy wiring 48 includes a first dummy pattern 48A and a second dummy pattern 48B. The first dummy pattern 48A and the second dummy pattern 48B are composed of a material containing one or more selected from Ti, TiN, Au, Ag, Cu, Al, and W.

The first dummy pattern 48A surrounds the second dummy wiring portion 47B in plain view. The first dummy pattern 48A is electrically independent from the second coil 42. That is, the first dummy pattern 48A is not electrically connected to the second coil 42.

The first dummy pattern 48A is formed by multiple wires. In an example, the wires each form a closed loop. The wires of the first dummy pattern 48A have the same wiring width as that of the second coil wiring 45. The first dummy pattern 48A has a greater wiring interval than that of the second coil wiring 45. That is, the first dummy pattern 48A has a lower density (wiring density) than that of the second coil wiring 45. The density of the first dummy pattern 48A may be equal to, or different from, the density of the second coil wiring 45.

As shown in FIG. 8, the first dummy pattern 48A and the outer dummy wiring 47 are located at the same position as the second coil 42 in the Z-direction. That is, the first dummy pattern 48A and the outer dummy wiring 47 are located farther away from the third semiconductor substrate 71 than the first coil 41 is in the Z-direction. The first dummy pattern 48A and the outer dummy wiring 47 suppress concentration of the electric field around the second coil 42, while limiting increases in the electric field intensity around the second coil 42.

As shown in FIG. 7, the second dummy pattern 48B is located between the second coil 42 and the electrode pad 73 (refer to FIG. 5) in plain view. The second dummy pattern 48B extends in the X-direction. In the example shown in FIG. 7, the second dummy pattern 48B is formed by a single wire extending in the X-direction. The second dummy pattern 48B may be formed by multiple wires extending in the X-direction. In this case, these wires are spaced apart from each other in the Y-direction. The second dummy pattern 48B is electrically independent from the second coil 42. That is, the second dummy pattern 48B is not electrically connected to the second coil 42.

As shown in FIG. 8, the isolator chip 70 includes the passivation film 78, and the resin layer 79 formed on the passivation film 78. The passivation film 78 protects the third insulating layer 72. The third insulating layer 72 and the passivation film 78 are examples of an “insulator”. Furthermore, the third insulating layer 72, the passivation film 78, and the resin layer 79 are examples of an “insulator”.

The passivation film 78 may be referred to as a surface protection film for the isolator chip 70. The passivation film 78 is formed on the upper surface of the third insulating layer 72. The passivation film 78 is composed of, for example, a material containing at least one of a silicon oxide film and a silicon nitride film. Examples of the material containing a silicon nitride film include SiN and SiCN.

The electrode pads 73 and 74 are covered by the passivation film 78. The passivation film 78 includes openings that partially expose the electrode pads 73 and 74. Accordingly, the exposed surface of the electrode pad 73 is used for connection with the wire W2 (refer to FIG. 3), and the exposed surface of the electrode pad 74 is used for connection with the wire W3 (refer to FIG. 3).

The resin layer 79 is composed of, for example, a material containing polyimide (PI). As shown in FIG. 4, the resin layer 79 is separated into an inner resin layer and an outer resin layer by a separation trench 79A. The separation trench 79A surrounds the transformers 40A and 40B (refer to FIG. 5) in plain view. The resin layer 79 includes a first resin opening 79B exposing the electrode pad 73, and a second resin opening 79C exposing the electrode pad 74.

As shown in FIG. 8, in the first embodiment, the third bonding material 113 is in contact with the entire lower surface of the third semiconductor substrate 71. The third bonding material 113 spreads outward from the third semiconductor substrate 71 toward the first die pad 81. The third bonding material 113 may be, for example, an insulative bonding material having a lower relative permittivity than the third semiconductor substrate 71. In a case in which the third semiconductor substrate 71 is a Si substrate, the third semiconductor substrate 71 has a relative permittivity of approximately 12. Accordingly, the third bonding material 113 may be an insulative bonding material having a relative permittivity of less than 12.

In an example, the third bonding material 113 may be an insulative bonding material having a relative permittivity of 1/2 or less of the relative permittivity of the third semiconductor substrate 71. In an example, the third bonding material 113 may be an insulative bonding material having a relative permittivity of 1/3 or less of the relative permittivity of the third semiconductor substrate 71. In an example, the third bonding material 113 is composed of an insulation material having a relative permittivity of less than 4. In an example, the third bonding material 113 may have the same relative permittivity as the encapsulation resin 100. In an example, the third bonding material 113 may have a lower relative permittivity than the encapsulation resin 100. In the first embodiment, the third bonding material 113 has a relative permittivity of 3.5.

### Method for Manufacturing Semiconductor Device

An exemplary method for manufacturing the semiconductor device 10 in accordance with the present embodiment will now be described. In the description hereafter, components related to the semiconductor device 10 will be denoted by the reference characters assigned to the components of the semiconductor device 10 shown in FIGS. 1 to 8.

The method for manufacturing the semiconductor device 10 mainly includes a step of preparing lead frames, a step of mounting chips, a step of forming wires, a step of forming an encapsulation resin, and a step of singulation.

In the step of preparing lead frames, the first lead frame 80 and the second lead frame 90 are prepared. For example, metal plates composed of a material containing Cu are etched to form the first lead frame 80 and the second lead frame 90, which include the die pads 81 and 91 and the leads 82 and 92. The first lead frame 80 and the second lead frame 90 may be formed by stamping.

The step of mounting chips includes a step of mounting the first chip 50 and the second chip 60, and a step of mounting the isolator chip 70.

In the step of mounting the first chip 50 and the second chip 60, first, the first bonding material 111 is applied to the first die pad 81, and the second bonding material 112 is applied to the second die pad 91. The first bonding material 111 and the second bonding material 112 are both conductive bonding materials. In an example, the first bonding material 111 and the second bonding material 112 are solder pastes. Next, the first chip 50 is placed on the first bonding material 111, and the second chip 60 is placed on the second bonding material 112. Then, reflow soldering is performed to melt the first bonding material 111 and the second bonding material 112. Subsequently, the first bonding material 111 and the second bonding material 112 are cooled and solidified. In this manner, the first chip 50 is mounted on the first die pad 81, and the second chip 60 is mounted on the second die pad 91.

In the step of mounting the isolator chip 70, first, the third bonding material 113 is applied to the first die pad 81. The third bonding material 113 is an insulative bonding material. In an example, the third bonding material 113 is a paste of a bonding material containing an epoxy resin. Next, the isolator chip 70 is placed on the third bonding material 113. When the third bonding material 113 is solidified, the isolator chip 70 is bonded to the first die pad 81. In this manner, the isolator chip 70 is mounted on the first die pad 81.

In the step of forming wires, the wires W1 to W4 are formed by, for example, a wire bonding device. In an example, the wire bonding device separately forms the wires W1 from the electrode pads 53 of the first chip 50 toward the first leads 82. In an example, the wire bonding device separately forms the wires W4 from the electrode pads 63 of the second chip 60 toward the second leads 92. In an example, the wire bonding device forms the wires W2 from the electrode pads 73 of the isolator chip 70 toward the electrode pads 53 of the first chip 50. In an example, the wire bonding device forms the wires W3 from the electrode pads 74 of the isolator chip 70 toward the electrode pads 63 of the second chip 60.

In the step of forming an encapsulation resin, the encapsulation resin 100 is formed by, for example, transfer molding. The encapsulation resin 100 entirely encapsulates the first chip 50, the second chip 60, the isolator chip 70, the first die pad 81, the second die pad 91, and the wires W1 to W4, and partially encapsulates the leads 82 and 92.

In the singulating step, the leads 82 and 92 projecting out of the encapsulation resin 100 are cut off using a dicing blade or a mold. The semiconductor device 10 is manufactured by the above-described procedure.

### Operation of the First Embodiment

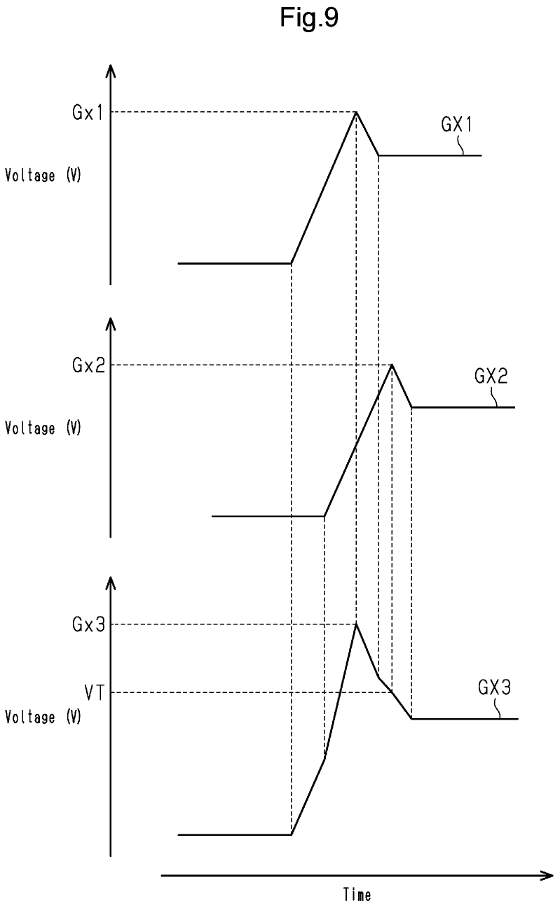

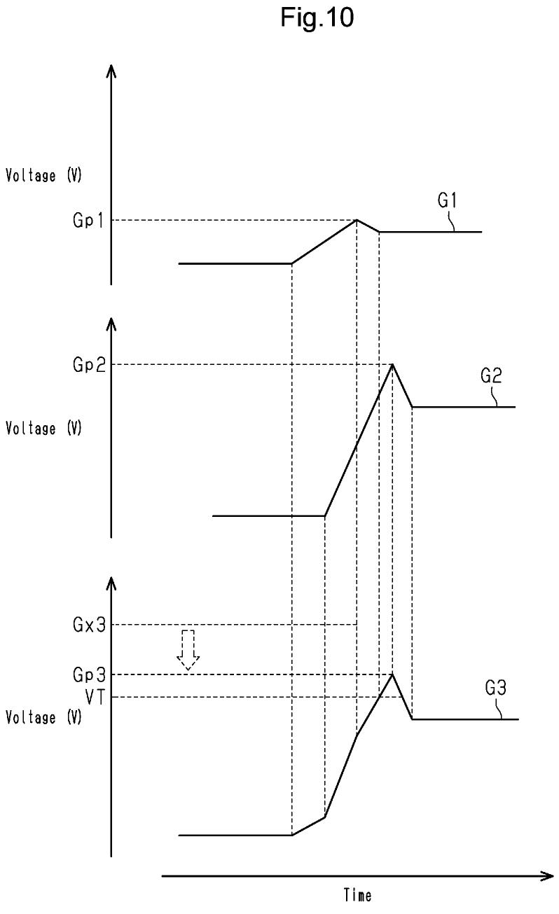

The operation of the semiconductor device 10 in accordance with the first embodiment will now be described with reference to FIGS. 9 and 10. FIG. 9 shows changes in the voltage applied to a coil of an isolator chip included in a comparative semiconductor device during a surge withstand capability test. FIG. 10 shows changes in the voltage applied to the first coil 41 of the isolator chip 70 included in the semiconductor device 10 in accordance with the first embodiment during a surge withstand capability test. The comparative semiconductor device mainly differs from the semiconductor device 10 of the first embodiment in that the isolator chip 70 and the first die pad 81 are bonded by a conductive bonding material.

In the surge withstand capability test of the semiconductor devices, the first leads 82 were short-circuited, and the second leads 92 were short-circuited. Further, the second leads 92 were grounded. Then, a predetermined surge voltage VT (e.g., 10000V, 1ns) was applied to the first leads 82.

The surge voltage was applied to the first coil 41 of the isolator chip 70 mainly through two different paths. These two paths will now be described with reference to FIGS. 2 and 3. The first path extends from the first leads 82 (82A) through the first die pad 81, the third bonding material 113 (conductive bonding material in comparative semiconductor device), and the third semiconductor substrate 71 to the first coil 41. The second path extends from the first leads 82 (82A) through the wires W1, the first chip 50, and the wires W2 to the first coil 41. Since the second leads 92 (92A) were grounded, the voltage at the second coil 42 of the isolator chip 70 was the ground potential (0V).

Line GX1 in FIG. 9 and line G1 in FIG. 10 indicate changes in the voltage at the first coil 41 (voltage between second coil 42 and first coil 41) as a result of the surge voltage applied through the first path. Line GX2 in FIG. 9 and line G2 in FIG. 10 indicate changes in the voltage at the first coil 41 as a result of the surge voltage applied through the second path. Line GX3 in FIG. 9 and line G3 in FIG. 10 indicate overall changes in the voltage at the first coil 41 during the surge withstand capability test. The first coil 41 received the surge voltage through the first path and the second path. Therefore, line G3 (GX3), indicating the overall voltage at the first coil 41 during the surge withstand capability test, has a waveform obtained by combining line G1 (GX1) and line G2 (GX2).

As shown in FIG. 9, although lines GX1 and GX2 indicate similar voltage changes, the surge voltage was applied to the first coil 41 at a later time in line GX2 than in line GX1. As a result, as indicated by line GX3, a peak value Gx3 of the overall voltage applied to the first coil 41 became significantly higher than the predetermined surge voltage VT in the comparative semiconductor device. Accordingly, the peak value Gx3 of the voltage applied to the third insulating layer 72 may also become relatively high, as indicated by line GX3. This may accelerate dielectric breakdown of the third insulating layer 72 between the first coil 41 and the second coil 42.

In the comparative semiconductor device, the isolator chip 70 is bonded to the first die pad 81 by a conductive bonding material. Accordingly, in the first path, the surge voltage is transmitted to the first coil 41 by means of capacitive coupling (AC coupling) between the first coil 41 and the conductive bonding material, facing each other with the third semiconductor substrate 71 located in between. The capacitance between the conductive bonding material and the first coil 41 may be determined by the facing area, the distance, and the relative permittivity between the conductive bonding material and the first coil 41. The facing area is mainly determined by the area of the first coil 41 in plain view. The distance and the relative permittivity are mainly determined by the thickness of the third semiconductor substrate 71. In this manner, in the first path of the comparative semiconductor device, the surge voltage is applied to the first coil 41 by means of coupling through the capacitance Cs of the third semiconductor substrate 71.

In contrast, in the semiconductor device 10 of the first embodiment, the isolator chip 70 is bonded to the first die pad 81 by the third bonding material 113, which is an insulative bonding material. Accordingly, the first coil 41 faces the first die pad 81 with the third semiconductor substrate 71 and the third bonding material 113 mainly located in between. Therefore, in the first path, the surge voltage is applied to the first coil 41 through the capacitance Cp of the third bonding material 113, in addition to the capacitance Cs of the third semiconductor substrate 71. Between the first die pad 81 and the first coil 41, the capacitance Cp of the third bonding material 113 is connected in series to the capacitance Cs of the third semiconductor substrate 71. The capacitance of the third bonding material 113 may be determined by the thickness (distance) of the third bonding material 113, the relative permittivity of the third bonding material 113, and the facing area between the first die pad 81 and the third semiconductor substrate 71, facing each other with the third bonding material 113 located in between. Accordingly, the combined capacitance of the third bonding material 113 and the third semiconductor substrate 71 in the first path is less than the capacitance Cs of the third semiconductor substrate 71. Therefore, a relatively low surge voltage is applied through the first path to the first coil 41 included in the semiconductor device 10 of the first embodiment, as compared to the surge voltage applied through the first path to the first coil 41 of the comparative semiconductor device.

As shown in FIG. 10, although the voltage is applied to the third insulating layer 72 at a later time in line G2 than that in line G1, the combined capacitance of the third bonding material 113 and the third semiconductor substrate 71 in the first path is relatively small. Accordingly, the peak value Gp1 of line G1 is lower than the peak value Gx1 of the line GX1. The second path has the same structure in the comparative semiconductor device and the semiconductor device 10 of the present embodiment, such that the peak value Gx2 of line GX2 shown in FIG. 9 is equal to the peak value Gp2 of line G2. As a result, the peak value Gp3 of line G3 is lower than the peak value Gx3 of line GX3 shown in FIG. 9. In this manner, a relatively low surge voltage is applied to the first coil 41 included in the semiconductor device 10 of the first embodiment, as compared to the surge voltage applied to the first coil 41 of the comparative semiconductor device. This avoids acceleration of dielectric breakdown of the third insulating layer 72 between the first coil 41 and the second coil 42.

### Advantages of the First Embodiment

The semiconductor device 10 in accordance with the first embodiment has the following advantages.

(1-1) The semiconductor device 10 includes the first die pad 81, the second die pad 91, the first chip 50, the second chip 60, the isolator chip 70, the first bonding material 111, the second bonding material 112, and the third bonding material 113. The first die pad 81 and the second die pad 91 are insulated from each other. The first chip 50 is mounted on the first die pad 81. The second chip 60 is mounted on the second die pad 91. The isolator chip 70 is mounted on the first die pad 81 and is connected between the first chip 50 and the second chip 60. The first bonding material 111 is disposed between the first die pad 81 and the first chip 50 and bonds the first die pad 81 and the first chip 50. The second bonding material 112 is disposed between the second die pad 91 and the second chip 60 and bonds the second die pad 91 and the second chip 60. The third bonding material 113 is disposed between the first die pad 81 and the isolator chip 70 and bonds the first die pad 81 and the isolator chip 70. The isolator chip 70 includes the third semiconductor substrate 71, the third insulating layer 72 disposed on the third semiconductor substrate 71, and the transformers 40A and 40B disposed in the third insulating layer 72. The transformers 40A and 40B each include the first coil 41 and the second coil 42 that are insulated from each other. The third semiconductor substrate 71 is bonded to the first die pad 81 by the third bonding material 113. The third bonding material 113 is an insulative bonding material.

With this structure, the combined capacitance of the third bonding material 113 and the third semiconductor substrate 71 is relatively small, as compared to a structure in which the third bonding material 113 is a conductive bonding material. This may reduce a surge voltage applied to the first coil 41 of the isolator chip 70, thereby improving the surge withstand voltage of the semiconductor device 10.

(1-2) The third bonding material 113 is composed of an insulation material having a smaller relative permittivity than the semiconductor material of the third semiconductor substrate 71.

With this structure, the combined capacitance of the third bonding material 113 and the third semiconductor substrate 71 is relatively small, as compared to a structure in which the third bonding material 113 has a relative permittivity that is higher than or equal to that of the semiconductor material of the third semiconductor substrate 71. This may reduce a surge voltage applied to the first coil 41 of the isolator chip 70, thereby improving the surge withstand voltage of the semiconductor device 10.

(1-3) The third bonding material 113 is composed of an insulation material having a relative permittivity of less than 12.

With this structure, the combined capacitance of the third bonding material 113 and the third semiconductor substrate 71 is relatively small, as compared to a structure in which the third bonding material 113 is an insulation material having a relative permittivity of 12 or greater. This may reduce a surge voltage applied to the first coil 41 of the isolator chip 70, thereby improving the surge withstand voltage of the semiconductor device 10.

(1-4) The electrode pads 53 of the first chip 50, the electrode pads 63 of the second chip 60, and the electrode pads 73 and 74 of the isolator chip 70 are located at the same position in the Z-direction. The electrode pads 53 of the first chip 50 are separately electrically connected to the electrode pads 73 of the isolator chip 70 by the wires W2. The electrode pads 74 of the isolator chip 70 are separately electrically connected to the electrode pads 63 of the second chip 60 by the wires W3.

With this structure, the wires W2 and W3 can be readily formed, as compared to a structure in which the electrode pads 53 of the first chip 50, the electrode pads 63 of the second chip 60, and the electrode pads 73 and 74 of the isolator chip 70 are located at different positions in the Z-direction.

(1-5) The third bonding material 113 is composed of an insulation material having a relative permittivity of less than 4.

With this structure, the combined capacitance of the third bonding material 113 and the third semiconductor substrate 71 is relatively small, as compared to a structure in which the third bonding material 113 is composed of an insulation material having a relative permittivity of 4 or greater. This may reduce a surge voltage applied to the first coil 41 of the isolator chip 70, thereby improving the surge withstand voltage of the semiconductor device 10.

### Second Embodiment

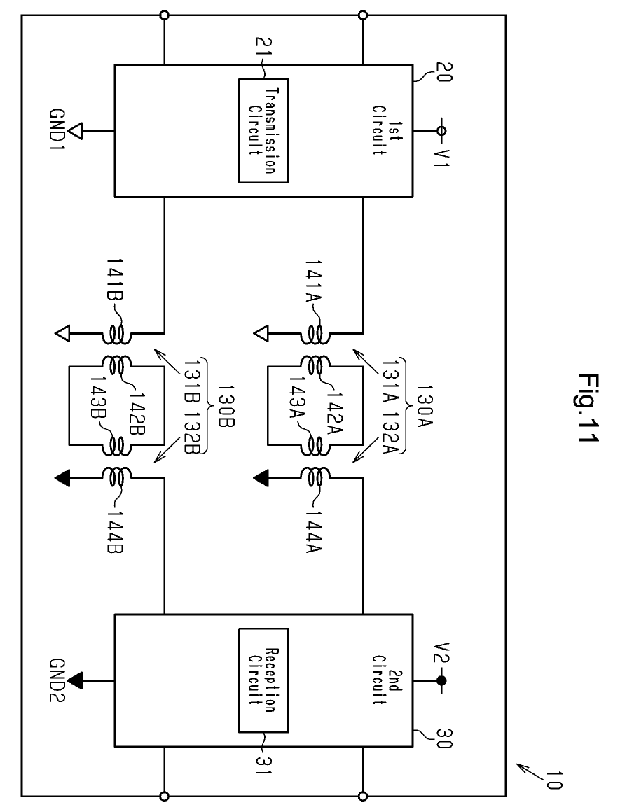

A semiconductor device 10 in accordance with a second embodiment will now be described with reference to FIGS. 11 to 13. The semiconductor device 10 of the second embodiment differs from that of the first embodiment in that the transformers have a double isolation structure. The description hereafter will focus on the differences from the first embodiment. Same reference characters are given to those components that are the same as the corresponding components of the semiconductor device 10 in the first embodiment, and such components will not be described in detail.

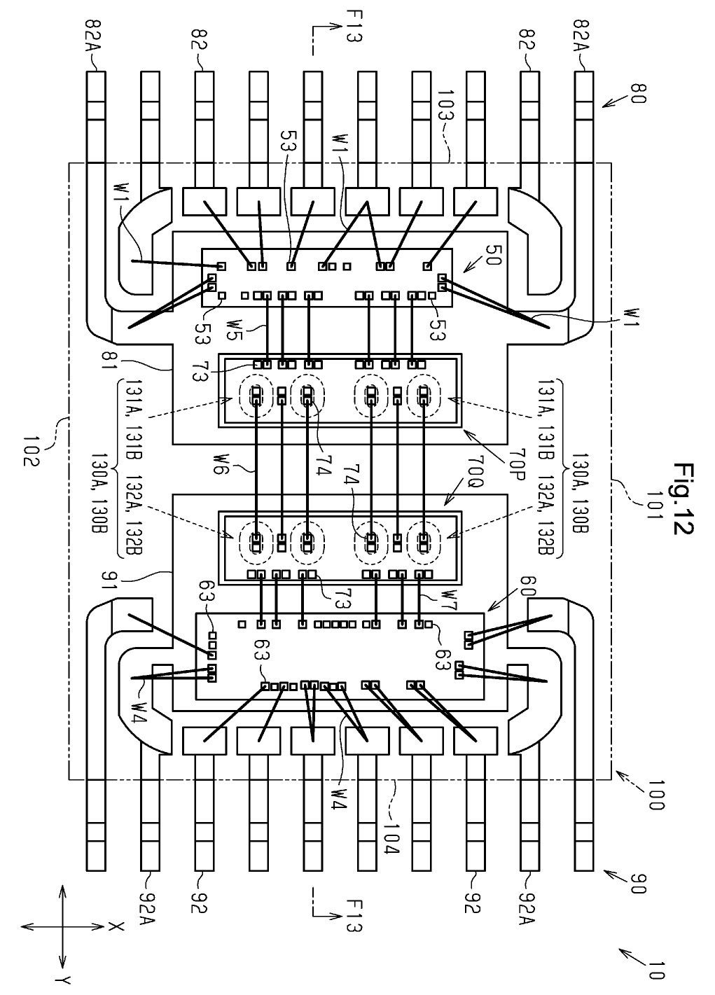

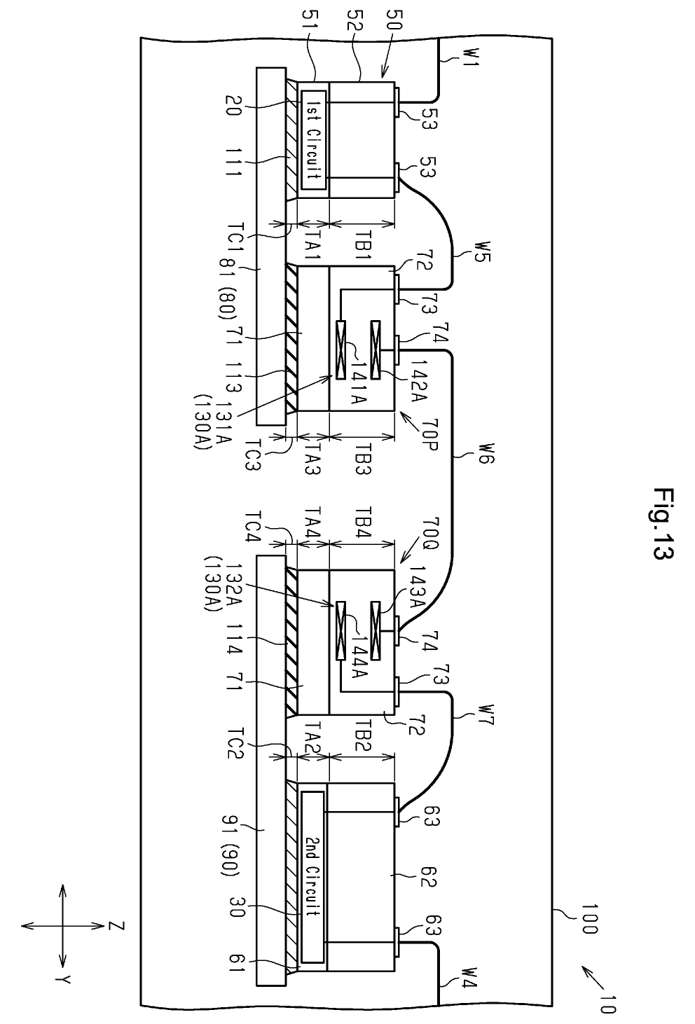

FIG. 11 is a schematic diagram showing the electrical configuration of the semiconductor device 10 in accordance with the second embodiment. FIG. 12 is a schematic view showing the internal structure of the semiconductor device 10 in accordance with the second embodiment. FIG. 13 is a schematic cross-sectional view of the semiconductor device 10 in accordance with the second embodiment, taken along line F13-F13 shown in FIG. 12.

As shown in FIG. 11, the semiconductor device 10 includes transformers 130A and 130B that electrically isolate the first circuit 20 and the second circuit 30. In an example, in the same manner as the first embodiment, the transformer 130A is used for transmitting a SET signal, and the transformer 130B is used for transmitting a RESET signal.

The transformer 130A includes a first transformer 131A and a second transformer 132A connected in series.

The first transformer 131A includes a first coil 141A and a second coil 142A. The second coil 142A is electrically isolated from the first coil 141A and is configured to be magnetically coupled to the first coil 141A. The second transformer 132A includes a third coil 143A and a fourth coil 144A. The fourth coil 144A is electrically isolated from the third coil 143A and is configured to be magnetically coupled to the third coil 143A.

The first coil 141A is electrically connected to the first circuit 20. The fourth coil 144A is electrically connected to the second circuit 30. The second coil 142A and the third coil 143A are electrically floating and are electrically connected to each other.

The transformer 130B includes a first transformer 131B and a second transformer 132B connected in series.

The first transformer 131B includes a first coil 141B and a second coil 142B. The second coil 142B is electrically isolated from the first coil 141B and is configured to be magnetically coupled to the first coil 141B. The second transformer 132B includes a third coil 143B and a fourth coil 144B. The fourth coil 144B is electrically isolated from the third coil 143B and is configured to be magnetically coupled to the third coil 143B.

The first coil 141B is electrically connected to the first circuit 20. The fourth coil 144B is electrically connected to the second circuit 30. The second coil 142B and the third coil 143B are electrically floating and are electrically connected to each other.

As shown in FIG. 12, the semiconductor device 10 includes a first isolator chip 70P and a second isolator chip 70Q. The first isolator chip 70P and the second isolator chip 70Q are both disposed between the first chip 50 and the second chip 60 in the Y-direction. The first isolator chip 70P is located closer to the first chip 50 than the second isolator chip 70Q is.

The first isolator chip 70P basically has the same structure as the isolator chip 70 (refer to FIG. 2) of the first embodiment. Instead of the first coils 41 and the second coils 42 of the transformers 40A and 40B (shown in FIG. 3) of the isolator chip 70 in accordance with the first embodiment, the first isolator chip 70P includes the first transformers 131A and 131B of the transformers 130A and 130B. The first coil 141A and the second coil 142A of the first transformer 131A and the first coil 141B and the second coil 142B of the first transformer 131B are disposed in the third insulating layer 72. The structures and arrangement of the first coils 141A and 141B and the second coils 142A and 142B are the same as those of the first coils 41 and the second coils 42 in the first embodiment.

As shown in FIG. 13, in the first isolator chip 70P, the first coil 141A of the first transformer 131A is electrically connected to the electrode pad 73. Further, the second coil 142A is electrically connected to the electrode pad 74. Although not shown in the drawings, in the first isolator chip 70P, the first coil 141B of the first transformer 131B is electrically connected to the electrode pad 73. Further, the second coil 142B is electrically connected to the electrode pad 74.

The first isolator chip 70P is mounted on the first die pad 81. The first isolator chip 70P is bonded to the first die pad 81 by the third bonding material 113. In the same manner as the first embodiment, the third bonding material 113 is an insulative bonding material. The insulative bonding material may be, for example, a material containing an epoxy resin. The third bonding material 113 of the second embodiment may have the same relative permittivity as, for example, that of the third bonding material 113 of the first embodiment.

In the second embodiment, the third bonding material 113 is in contact with the entire lower surface of the third semiconductor substrate 71 of the first isolator chip 70P. The third bonding material 113 spreads outward from the third semiconductor substrate 71 toward the first die pad 81.

The second isolator chip 70Q basically has the same structure as the first isolator chip 70P. Instead of the first coils 141A and 141B and the second coils 142A and 142B of the first transformers 131A and 131B of the first isolator chip 70P, the second isolator chip 70Q includes the third coils 143A and 143B and the fourth coils 144A and 144B of the second transformers 132A and 132B. The structures and arrangement of the third coils 143A and 143B are the same as those of the second coils 142A and 142B of the first isolator chip 70P. The structures and arrangement of the fourth coils 144A and 144B are the same as those of the first coils 141A and 141B of the first isolator chip 70P. The fourth coil 144A is electrically connected to the electrode pad 73. The third coil 143A is electrically connected to the electrode pad 74.

In the second isolator chip 70Q, the third coil 143A of the second transformer 132A is electrically connected to the electrode pad 74. Further, the fourth coil 144A of the second transformer 132A is electrically connected to the electrode pad 73. Although not shown in the drawings, in the second isolator chip 70Q, the third coil 143B of the second transformer 132B is electrically connected to the electrode pad 74. Further, the fourth coil 144B of the second transformer 132B is electrically connected to the electrode pad 73.

The second isolator chip 70Q is mounted on the second die pad 91. The second isolator chip 70Q is bonded to the second die pad 91 by a fourth bonding material 114. The fourth bonding material 114 is disposed between the second die pad 91 and the second isolator chip 70Q. In the second embodiment, the fourth bonding material 114 is a conductive bonding material. The conductive bonding material is, for example, a solder paste or an Ag paste.

In the second embodiment, the first chip 50, the second chip 60, the first isolator chip 70P, and the second isolator chip 70Q have the following relationship in terms of their thicknesses. The thickness TA3 of the third semiconductor substrate 71 of the first isolator chip 70P is equal to a thickness TA4 of the third semiconductor substrate 71 of the second isolator chip 70Q. The thicknesses TA3 and TA4 of the third semiconductor substrate 71 of the isolator chips 70P and 70Q are equal to the thickness TA1 of the first semiconductor substrate 51. The thicknesses TA3 and TA4 of the third semiconductor substrate 71 of the isolator chips 70P and 70Q are equal to the thickness TA2 of the second semiconductor substrate 61. The thickness TB3 of the third insulating layer 72 of the first isolator chip 70P is equal to a thickness TB4 of the third insulating layer 72 of the second isolator chip 70Q. The thicknesses TB3 and TB4 of the third insulating layer 72 of the isolator chips 70P and 70Q are equal to the thickness TB1 of the first insulating layer 52. The thicknesses TB3 and TB4 of the third insulating layer 72 of the isolator chips 70P and 70Q are equal to the thickness TB2 of the second insulating layer 62. The thickness TC3 of the third bonding material 113 is equal to the thickness TC1 of the first bonding material 111. The thickness TC3 of the third bonding material 113 is equal to the thickness TC2 of the second bonding material 112. The thickness TC3 of the third bonding material 113 is equal to a thickness TC4 of the fourth bonding material 114.

The semiconductor device 10 of the second embodiment includes wires W5 to W7, instead of the wires W2 and W3 of the first embodiment.

The wires W5 separately connect the electrode pads 53 of the first chip 50 to the electrode pads 73 of the first isolator chip 70P. The wires W6 separately connect the electrode pads 74 of the first isolator chip 70P to the electrode pads 74 of the second isolator chip 70Q. The wires W7 separately connect the electrode pads 63 of the second chip 60 to the electrode pads 73 of the second isolator chip 70Q.

The encapsulation resin 100 encapsulates the first chip 50, the second chip 60, the first isolator chip 70P, the second isolator chip 70Q, the first die pad 81, the second die pad 91, and the wires W1, W4, and W5 to W7. The encapsulation resin 100 partially encapsulates the leads 82 and 92.

### Advantages of the Second Embodiment

The semiconductor device 10 in accordance with the second embodiment has the following advantages.

(2-1) The semiconductor device 10 includes the first isolator chip 70P, the second isolator chip 70Q, and the fourth bonding material 114. The first isolator chip 70P is mounted on the first die pad 81. The second isolator chip 70Q is mounted on the second die pad 91. The fourth bonding material 114 is disposed between the second die pad 91 and the second isolator chip 70Q and bonds the second die pad 91 and the second isolator chip 70Q. With this structure, the first isolator chip 70P and the second isolator chip 70Q form a double isolation structure. This improves the dielectric breakdown voltage of the semiconductor device 10.

(2-2) The first isolator chip 70P and the second isolator chip 70Q have the same structure.

This structure may reduce the manufacturing costs of the first isolator chip 70P and the second isolator chip 70Q, as compared to a structure in which the first isolator chip 70P and the second isolator chip 70Q have different structures.

(2-3) The electrode pads 53 of the first chip 50, the electrode pads 63 of the second chip 60, the electrode pads 73 and 74 of the first isolator chip 70P, and the electrode pads 73 and 74 of the second isolator chip 70Q are located at the same position in the Z-direction. The electrode pads 53 of the first chip 50 are separately electrically connected to the electrode pads 73 of the first isolator chip 70P by the wires W5. The electrode pads 74 of the first isolator chip 70P are separately electrically connected to the electrode pads 74 of the second isolator chip 70Q by the wires W6. The electrode pads 73 of the second isolator chip 70Q are separately electrically connected to the electrode pads 63 of the second chip 60 by the wires W7.

With this structure, the wires W5 to W7 can be readily formed, as compared to a structure in which the electrode pads 53 of the first chip 50, the electrode pads 63 of the second chip 60, the electrode pads 73 and 74 of the first isolator chip 70P, and the electrode pads 73 and 74 of the second isolator chip 70Q are located at different positions in the Z-direction.

### Third Embodiment

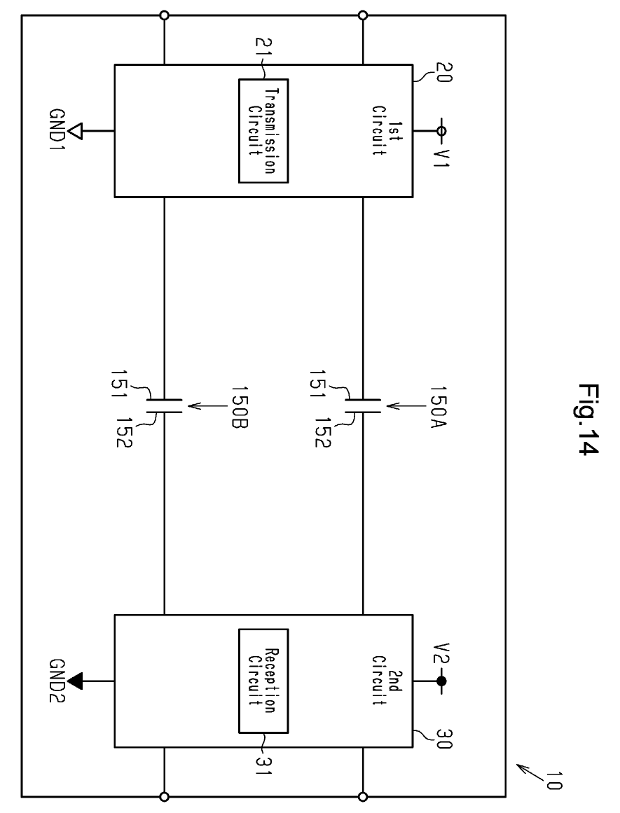

A semiconductor device 10 in accordance with a third embodiment will now be described with reference to FIGS. 14 to 16. The semiconductor device 10 of the third embodiment differs from that of the first embodiment in that an isolation structure is obtained by capacitors, instead of the transformers. The description hereafter will focus on the differences from the first embodiment. Same reference characters are given to those components that are the same as the corresponding components of the semiconductor device 10 in the first embodiment, and such components will not be described in detail.

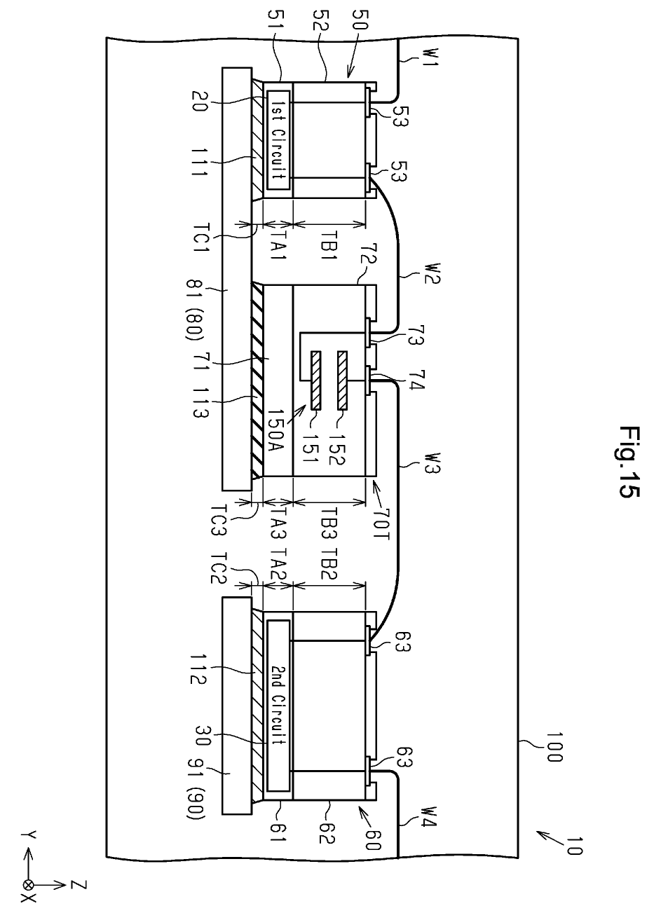

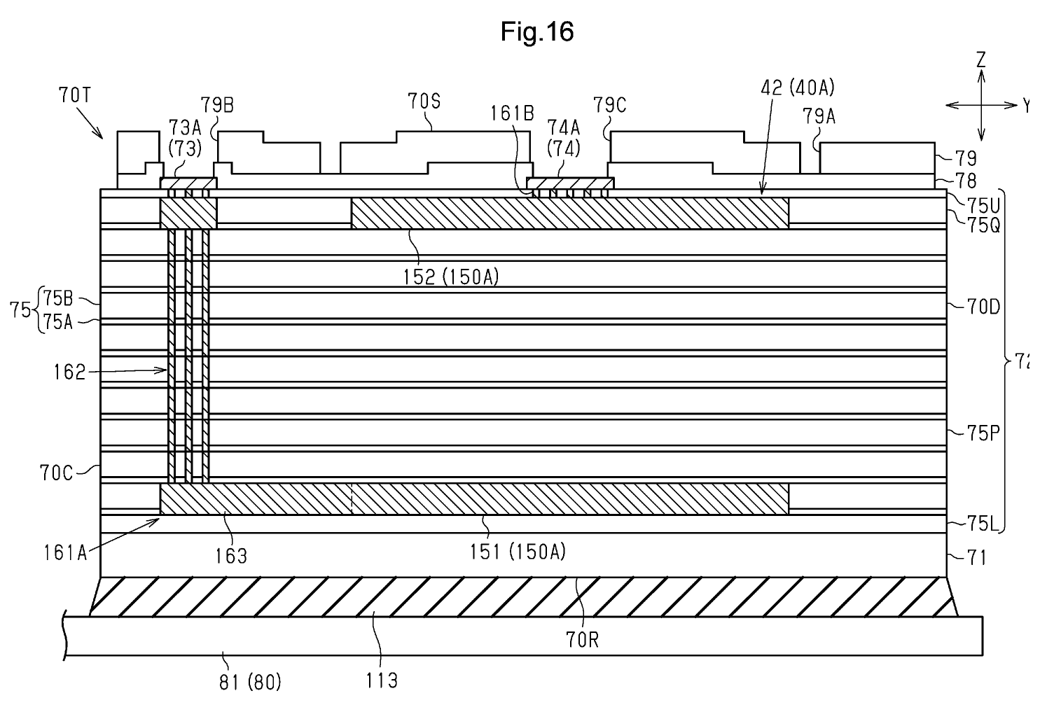

FIG. 14 is a schematic diagram showing the electrical configuration of the semiconductor device 10 in accordance with the third embodiment. FIG. 15 is a schematic cross-sectional view of the semiconductor device 10 in accordance with the third embodiment. The cross section shown in FIG. 15 is taken at the same position as that of the cross section shown in FIG. 3. FIG. 16 is a schematic cross-sectional view of an isolator chip 70T, which will be described later. The cross section shown in FIG. 16 is taken at the same position as that of the cross section shown in FIG. 8.

As shown in FIG. 14, the semiconductor device 10 includes capacitors 150A and 150B, instead of the transformers 40A and 40B. The capacitors 150A and 150B are configured to electrically isolate the first circuit 20 and the second circuit 30. In an example, in the same manner as the first embodiment, the capacitor 150A is used for transmitting a SET signal, and the capacitor 150B is used for transmitting a RESET signal. The capacitors 150A and 150B are examples of an “isolation element”.

The capacitors 150A and 150B each include a first electrode 151 and a second electrode 152. The first electrodes 151 of the capacitors 150A and 150B are electrically connected to the first circuit 20. The second electrodes 152 of the capacitors 150A and 150B are electrically connected to the second circuit 30.

As shown in FIG. 15, the semiconductor device 10 includes the isolator chip 70T, instead of the isolator chip 70. The isolator chip 70T includes the capacitors 150A and 150B. Accordingly, the isolator chip 70T may also be referred to as a capacitor chip.

The isolator chip 70T is disposed between the first chip 50 and the second chip 60 in the Y-direction. The isolator chip 70T is mounted on the first die pad 81. The isolator chip 70T is bonded to the first die pad 81 by the third bonding material 113. The third bonding material 113 is the same as that of the first embodiment.

As shown in FIG. 16, the capacitors 150A and 150B are disposed in the third insulating layer 72. The first electrodes 151 and the second electrodes 152 of the capacitors 150A and 150B face each other in the Z-direction. The first electrodes 151 are located closer to the third semiconductor substrate 71 than the second electrodes 152 are. The first electrodes 151 and the second electrodes 152 each have a rectangular plate shape and have a thickness in the Z-direction. The first electrode 151 and the second electrode 152 are examples of an “electrode plate”. The first electrode 151 is an example of a “first conductive layer”. The second electrode 152 is an example of a “second conductive layer”.

The first electrode 151 is disposed in the insulating film 75P of the third insulating layer 72. More specifically, the insulating film 75P includes a first capacitor groove that extends through the first insulating film 75A and the second insulating film 75B in the Z-direction. The first electrode 151 is formed by embedding a conductive layer in the first capacitor groove. The first electrode 151 is covered by the insulating film 75P, and the insulating films 75 located next to the insulating film 75P in the Z-direction. In other words, the first electrode 151 is embedded in the third insulating layer 72.

The second electrode 152 is disposed in the insulating film 75Q of the third insulating layer 72. More specifically, the insulating film 75Q includes a second capacitor groove that extends through the first insulating film 75A and the second insulating film 75B in the Z-direction. The second electrode 152 is formed by embedding a conductive layer in the second capacitor groove. The second electrode 152 is covered by the insulating film 75Q, and the insulating films 75 located next to the insulating film 75Q in the Z-direction. In other words, the second electrode 152 is embedded in the third insulating layer 72.

The first electrode 151 is electrically connected to the electrode pad 73 by an interconnect 161A. The interconnect 161A includes a first interconnect portion 162 extending through multiple insulating films 75 in the Z-direction, and a second interconnect portion 163 extending in a direction (Y-direction in FIG. 16) orthogonal to the Z-direction.

The first interconnect portion 162 is located at a position that overlaps the first pad 73A in plain view. The first interconnect portion 162 is connected to the first pad 73A. In an example, the first interconnect portion 162 extends through multiple insulating films 75 from the uppermost insulating film 75U to the insulating film 75 that is the second film above the lowermost insulating film 75L. The first interconnect portion 162 includes flat wiring parts and multiple vias. Two wiring parts are respectively arranged in the insulating film 75Q, in which the electrodes 151 and 152 are disposed. The vias extend in the Z-direction, between the upper wiring part and the first pad 73A, and between the upper wiring part and the second interconnect portion 163.

The second interconnect portion 163 is located closer to the third semiconductor substrate 71 than the first interconnect portion 162 is. The second interconnect portion 163 is disposed in the insulating film 75P. That is, the second interconnect portion 163 and the first electrode 151 are located at the same position in the Z-direction. The second interconnect portion 163 is connected to the first interconnect portion 162. The second interconnect portion 163 has an end part located opposite to the first interconnect portion 162 in the Y-direction. This end part is connected to the first electrode 151.

The second electrode 152 is electrically connected to the electrode pad 74 by an interconnect 161B. The interconnect 161B is formed by, for example, multiple vias. For example, the vias extend through the uppermost insulating film 75U of the third insulating layer 72 in the Z-direction. The interconnects 161A and 161B are composed of a material containing one or more selected from Ti, TiN, Au, Ag, Cu, Al, and W.

### Advantages of the Third Embodiment

The semiconductor device 10 in accordance with the third embodiment has the following advantages, in addition to the advantages of the semiconductor device 10 in accordance with the first embodiment.

(3-1) The interconnect 161A includes the first interconnect portion 162 connected to the first pad 73A, and the second interconnect portion 163 connected to the first interconnect portion 162. The second interconnect portion 163 extends in a direction orthogonal to the Z-direction and is connected to the first electrode 151. The second interconnect portion 163 and the first electrode 151 are located at the same position in the Z-direction.

With this structure, the third insulating layer 72 may include a relatively small number of layered films, as compared to a structure in which the second interconnect portion 163 is located closer to the third semiconductor substrate 71 than the first electrode 151 is. This allows the isolator chip 70 to have a relatively low profile. Alternatively, in a case in which the number of layered films included in the third insulating layer 72 is not decreased, the third insulating layer 72 may include a relatively large number of layered films between the first electrode 151 and the second electrode 152, as compared to a structure in which the second interconnect portion 163 is located closer to the third semiconductor substrate 71 than the first electrode 151 is. This may improve the dielectric withstand voltage of the isolator chip 70.

### Modified Examples

The above-described embodiments may be modified as follows. The modified examples described below may be combined as long as there is no technical contradiction.

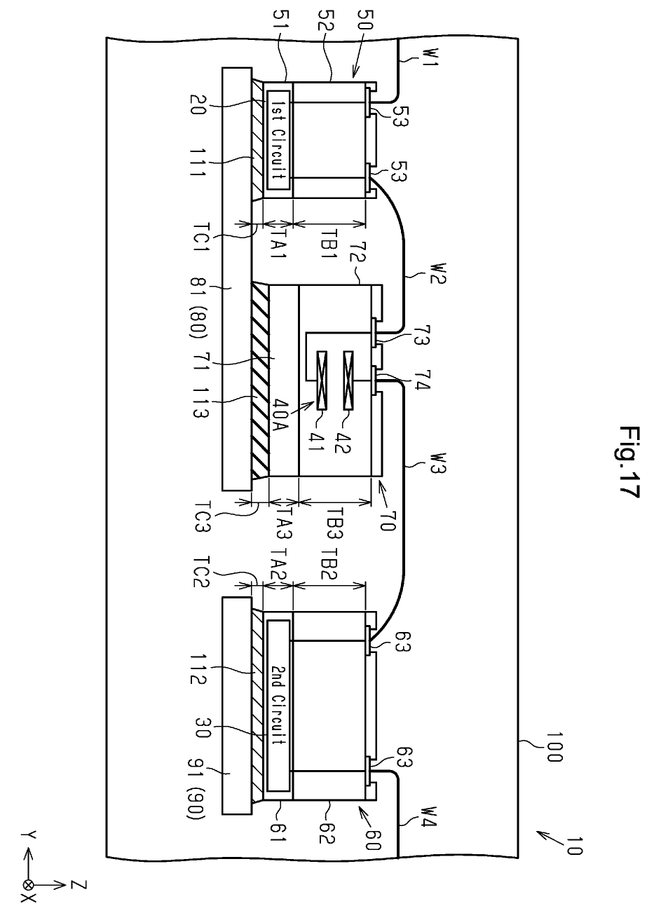

In the first and third embodiments, the relationships between the thicknesses TC1 to TC3 of the first to third bonding materials 111 to 113 may be changed. FIG. 17 is a schematic cross-sectional view of a modified example of the semiconductor device 10 of the first embodiment. As shown in FIG. 17, the thickness TC3 of the third bonding material 113 may be greater than the thickness TC1 of the first bonding material 111. The thickness TC3 of the third bonding material 113 may be greater than the thickness TC2 of the second bonding material 112.

In the example shown in FIG. 17, the thickness TA3 of the third semiconductor substrate 71 is equal to the thickness TA1 of the first semiconductor substrate 51 and the thickness TA2 of the second semiconductor substrate 61. The thickness TB3 of the third insulating layer 72 is equal to the thickness TB1 of the first insulating layer 52 and the thickness TB2 of the second insulating layer 62. Accordingly, the isolator chip 70 is greater in height than the first chip 50 and the second chip 60. In other words, the electrode pads 73 and 74 of the isolator chip 70 are located at higher positions than those of the electrode pads 53 of the first chip 50 and the electrode pads 63 of the second chip 60 in the Z-direction.

With this structure, the third bonding material 113 has a relatively large thickness TC3, so that the combined capacitance of the third bonding material 113 and the third semiconductor substrate 71 is relatively low. This may reduce a surge voltage applied to the first coil 41 of the isolator chip 70, thereby improving the surge withstand voltage of the semiconductor device 10.

In the second embodiment, the relationships between the thicknesses TC1 to TC4 of the first to fourth bonding materials 111 to 114 may be changed. In an example, in the same manner as the modified example of the semiconductor device 10 shown in FIG. 17, the thickness TC3 of the third bonding material 113 may be greater than the thickness TC1 of the first bonding material 111. The thickness TC3 of the third bonding material 113 may be greater than the thickness TC2 of the second bonding material 112. The thickness TC3 of the third bonding material 113 may be greater than the thickness TC4 of the fourth bonding material 114.

With this structure, the third bonding material 113 has a relatively large thickness TC3, so that the combined capacitance of the third bonding material 113 and the third semiconductor substrate 71 is relatively low. This may reduce a surge voltage applied to the first coil 41 of the isolator chip 70, thereby improving the surge withstand voltage of the semiconductor device 10.

Alternatively. the thickness TC3 of the third bonding material 113 may be equal to the thickness TC4 of the fourth bonding material 114. More specifically, the thickness TC3 of the third bonding material 113 and the thickness TC4 of the fourth bonding material 114 may both be greater than the thickness TC1 of the first bonding material 111 and the thickness TC2 of the second bonding material 112.

With this structure, the electrode pads 73 and 74 of the first isolator chip 70P and the electrode pads 73 and 74 of the second isolator chip 70Q are located at the same position in the Z-direction. Therefore, the wires W6 may be readily formed, as compared to a structure in which the electrode pads 73 and 74 of the first isolator chip 70P and the electrode pads 73 and 74 of the second isolator chip 70Q are located at different positions in the Z-direction.

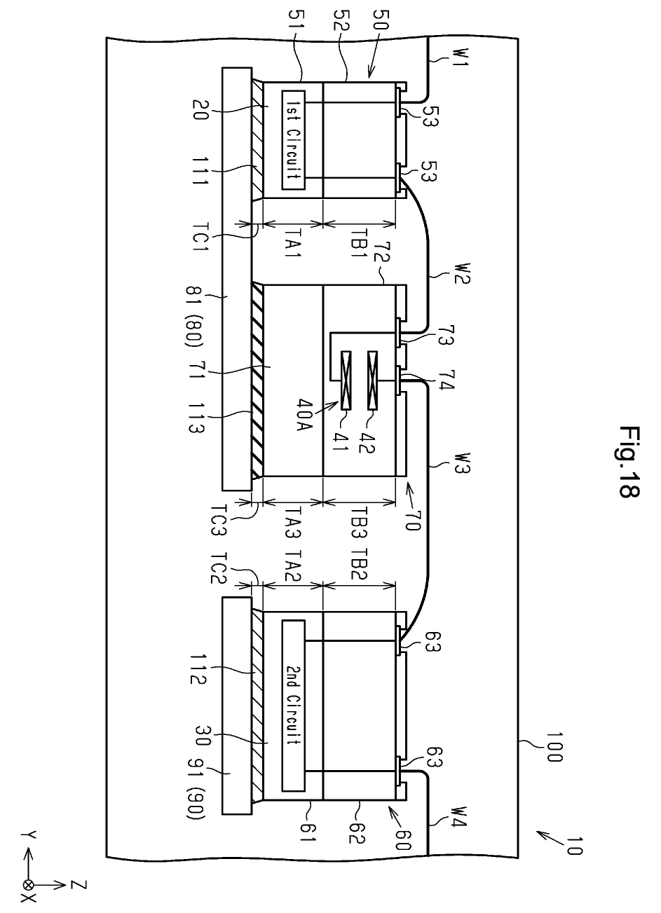

In each of the above-described embodiments, the thickness TA1 of the first semiconductor substrate 51, the thickness TA2 of the second semiconductor substrate 61, and the thickness TA3 of the third semiconductor substrate 71 may be changed. FIG. 18 is a schematic cross-sectional view of a first modified example of the semiconductor device 10 of the first embodiment. As shown in FIG. 18, the thickness TA1 of the first semiconductor substrate 51, the thickness TA2 of the second semiconductor substrate 61, and the thickness TA3 of the third semiconductor substrate 71 are respectively greater than the thickness TA1 of the first semiconductor substrate 51, the thickness TA2 of the second semiconductor substrate 61, and the thickness TA3 of the third semiconductor substrate 71 of the first embodiment. In the first modified example, the thickness TA1 of the first semiconductor substrate 51, the thickness TA2 of the second semiconductor substrate 61, and the thickness TA3 of the third semiconductor substrate 71 each may be greater than 180μm and less than or equal to 400μm.

With this structure, the third semiconductor substrate 71 has a relatively large thickness TA3, so that the combined capacitance of the third semiconductor substrate 71 and the third bonding material 113 is relatively low. This may reduce a surge voltage applied to the first coil 41 of the isolator chip 70, thereby improving the surge withstand voltage of the semiconductor device 10.

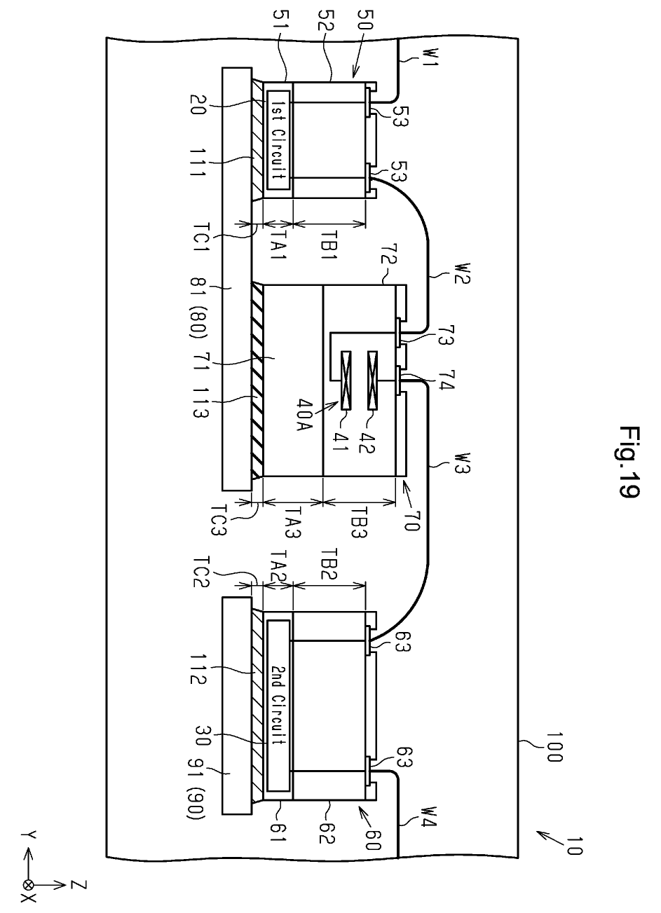

FIG. 19 is a schematic cross-sectional view of a second modified example of the semiconductor device 10 of the first embodiment. As shown in FIG. 19, the thickness TA3 of the third semiconductor substrate 71 may be greater than the thickness TA1 of the first semiconductor substrate 51. The thickness TA3 of the third semiconductor substrate 71 may be greater than the thickness TA2 of the second semiconductor substrate 61. The thickness TA3 of the third semiconductor substrate 71 may be greater than both of the thickness TA1 of the first semiconductor substrate 51 and the thickness TA2 of the second semiconductor substrate 61. In the second modified example, the thickness TA3 of the third semiconductor substrate 71 may be greater than 180μm and less than or equal to 400μm. In the second modified example, the thickness TA1 of the first semiconductor substrate 51 and the thickness TA2 of the second semiconductor substrate 61 are both approximately 180μm.

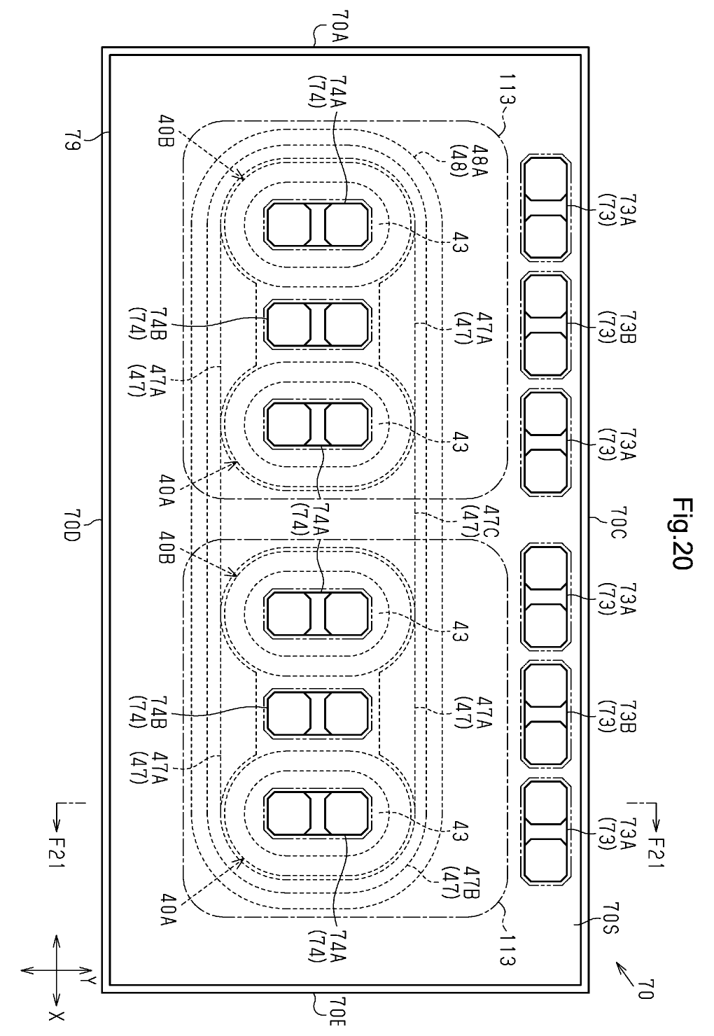

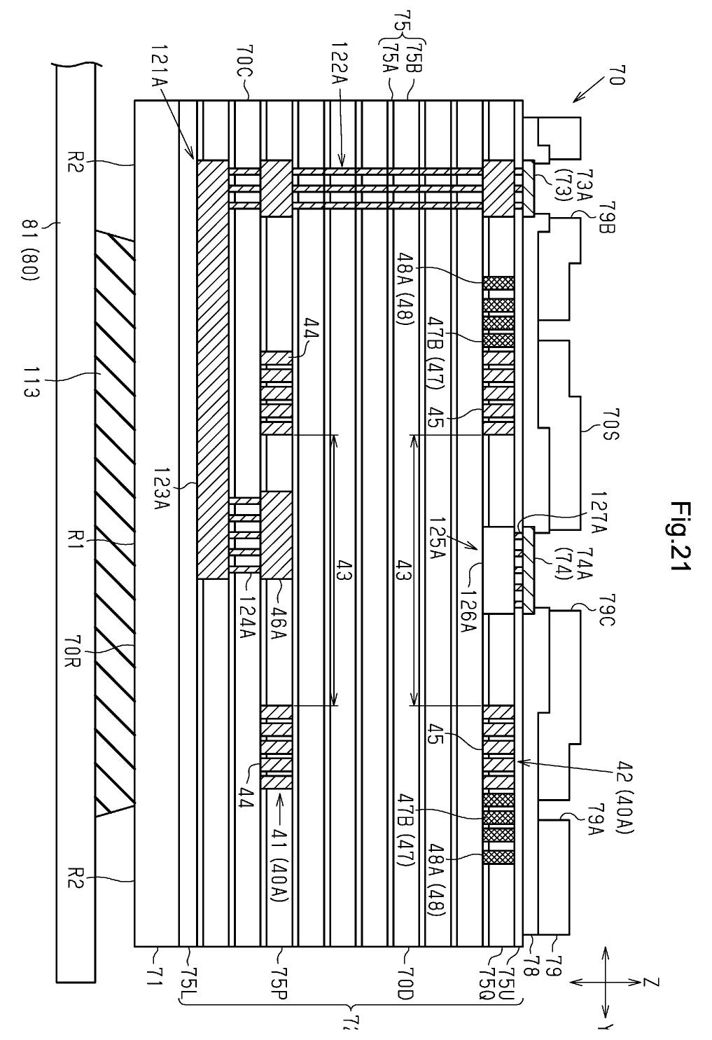

In each of the above-described embodiments, the area of contact between the third bonding material 113 and the isolator chip 70, 70T or the first isolator chip 70P may be changed. FIG. 20 is a schematic plan view of a modified example of the isolator chip 70. FIG. 21 is a schematic cross-sectional view taken along line F21-F21 shown in FIG. 20, showing the first die pad 81, the isolator chip 70, and the third bonding material 113, in a state in which the isolator chip 70 is bonded to the first die pad 81.

As indicated by single-dashed lines in FIG. 20, the third bonding material 113 includes separate parts arranged next to and spaced apart from each other in the X-direction. That is, the third bonding material 113 is partially in contact with the lower surface of the third semiconductor substrate 71.

As shown in FIG. 21, each part of the third bonding material 113 spreads outward from the third semiconductor substrate 71 toward the first die pad 81. The third bonding material 113 is an insulative bonding material, in the same manner as the third bonding material 113 of the first embodiment.

The chip lower surface 70R of the isolator chip 70 includes a first region R1 that is in contact with the third bonding material 113, and a second region R2 that is not in contact with the third bonding material 113. The encapsulation resin 100 (refer to FIG. 20) is in contact with the second region R2. That is, the gap between the second region R2 and the die pad 81 in the Z-direction is filled with the encapsulation resin 100.

With this structure, the area of contact between the third bonding material 113 and the third semiconductor substrate 71 is relatively small, so that the combined capacitance of the third semiconductor substrate 71 with the third bonding material 113 is relatively low. This may reduce a surge voltage applied to the first coil 41 of the isolator chip 70, thereby improving the surge withstand voltage of the semiconductor device 10.

In the present modified example, the third bonding material 113 is in contact with the lower surface of the third semiconductor substrate 71 at two different locations. However, there is no limit to such a structure. The third bonding material 113 may be in contact with the lower surface of the third semiconductor substrate 71 at three or more different locations.

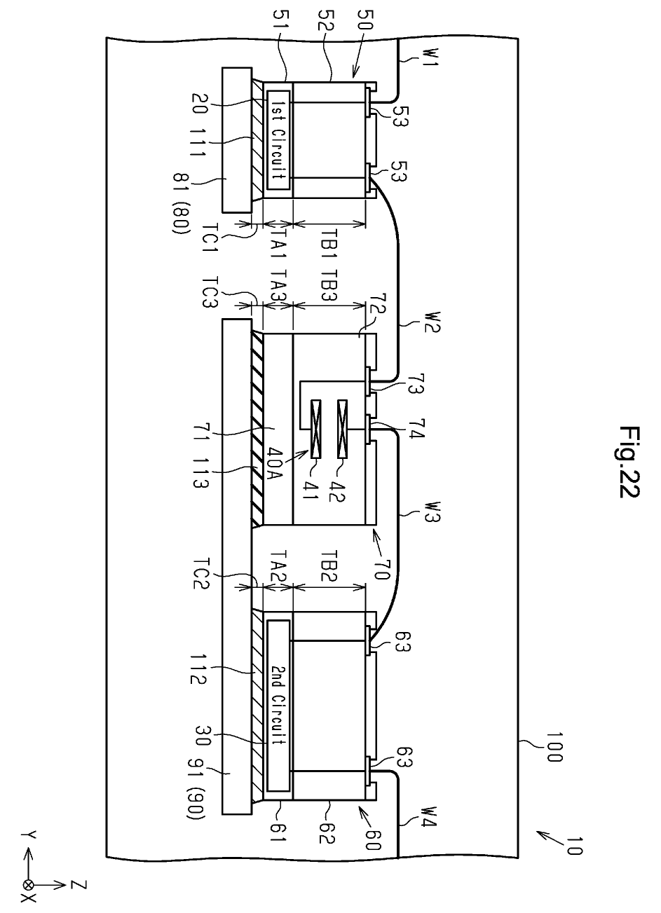

In the first and third embodiments, the positions of the isolator chips 70 and 70T may be changed. FIG. 22 is a schematic cross-sectional view of a modified example of the semiconductor device 10 of the first embodiment.

As shown in FIG. 22, the isolator chip 70 may be mounted on the second die pad 91. The isolator chip 70 is bonded to the second die pad 91 by the third bonding material 113. The third bonding material 113 is disposed between the second die pad 91 and the isolator chip 70. The third bonding material 113 is, for example, an insulative bonding material. In the same manner as the isolator chip 70, the isolator chip 70T may be mounted on the second die pad 91.

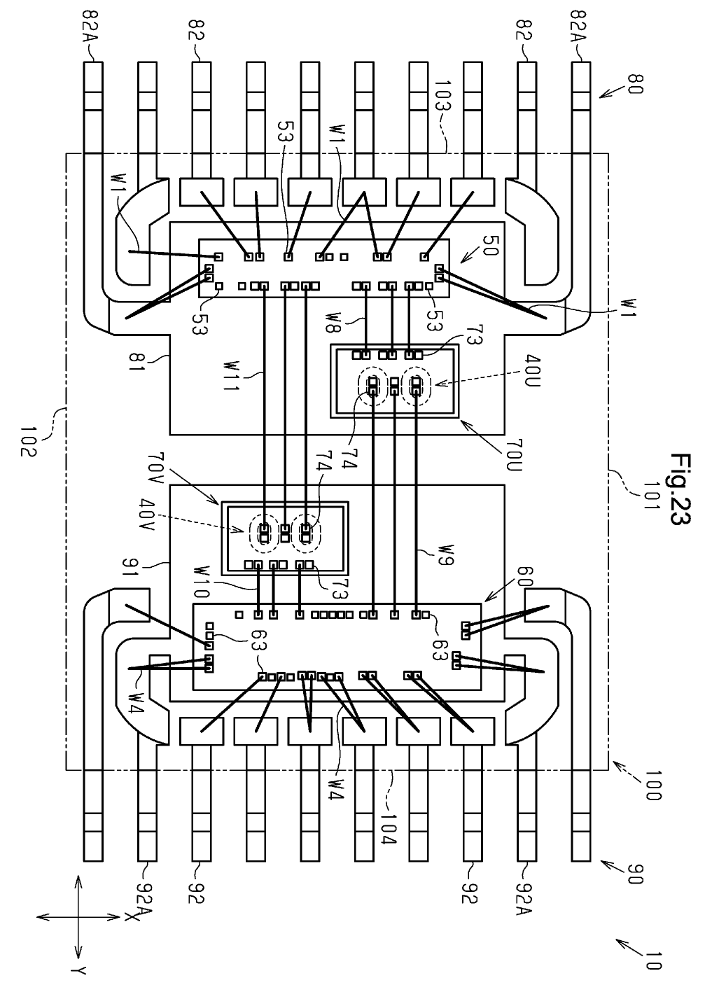

In the first and third embodiments, the semiconductor device 10 may be configured to bidirectionally transmit signals between the first circuit 20 and the second circuit 30. In an example, as shown in FIG. 23, the semiconductor device 10 includes a first isolator chip 70U and a second isolator chip 70V. The first isolator chip 70U is configured to transmit a first signal from the first circuit 20 toward the second circuit 30, which are shown in FIG. 1. The second isolator chip 70V is configured to transmit a second signal from the second circuit 30 toward the first circuit 20. In an example, the first isolator chip 70U and the second isolator chip 70V have the same structure. In an example, the first isolator chip 70U and the second isolator chip 70V have the same structure as that of the isolator chip 70.

The first isolator chip 70U includes a transformer 40U. The transformer 40U includes the first coil 41 and the second coil 42, which are shown in FIG. 1. The first coil 41 is electrically connected to the first circuit 20. The second coil 42 is electrically connected to the second circuit 30. The first isolator chip 70U is rectangular in plain view, with long sides extending in the X-direction and short sides extending in the Y-direction. The transformer 40U is an example of a “first isolation element”. The first coil 41 of the transformer 40U is an example of a “first conductive layer”. The second coil 42 of the transformer 40U is an example of a “second conductive layer”.

The first isolator chip 70U includes the electrode pads 73 and 74, in the same manner as the isolator chip 70. The electrode pads 73 are electrically connected to the first coil 41. The electrode pads 74 are electrically connected to the second coil 42.

The first isolator chip 70U is mounted on the first die pad 81. The first isolator chip 70U is disposed between the first chip 50 and the second chip 60 in the Y-direction. In plain view, the distance from the first isolator chip 70U to the second chip 60 in the Y-direction is greater than the distance from the first isolator chip 70U to the first chip 50 in the Y-direction. The first isolator chip 70U is connected to the first chip 50 and the second chip 60. The first isolator chip 70U is located at a position offset from the center of the first die pad 81 in the X-direction. In the example shown in FIG. 23, the first isolator chip 70U is located closer to the encapsulation side surface 101 than the center of the first die pad 81 is in the X-direction.

The first isolator chip 70U is bonded to the first die pad 81 by the third bonding material 113 (refer to FIG. 3). The third bonding material 113 bonds the first isolator chip 70U and the first die pad 81 in the same manner as the third bonding material 113 bonds the isolator chip 70 and the first die pad 81 in the first embodiment. The third bonding material 113, which bonds the first isolator chip 70U and the first die pad 81, is an insulative bonding material. This insulative bonding material is the same as, for example, the third bonding material 113 of the first embodiment.

The second isolator chip 70V includes a transformer 40V. The transformer 40V includes the first coil 41 and the second coil 42. The first coil 41 is electrically connected to the second circuit 30. The second coil 42 is electrically connected to the first circuit 20. The second isolator chip 70V is rectangular in plain view, with long sides extending in the X-direction and short sides extending in the Y-direction. In an example, the second isolator chip 70V has the same planar size as the first isolator chip 70U. The transformer 40V is an example of a “second isolation element”. The first coil 41 of the transformer 40V is an example of a “third conductive layer”. The second coil 42 of the transformer 40V is an example of a “fourth conductive layer”.

The second isolator chip 70V includes the electrode pads 73 and 74, in the same manner as the isolator chip 70. The electrode pads 73 are electrically connected to the first coil 41. The electrode pads 74 are electrically connected to the second coil 42.

The second isolator chip 70V is mounted on the second die pad 91. In plain view, the distance from the second isolator chip 70V to the first chip 50 in the Y-direction is greater than the distance from the second isolator chip 70V to the second chip 60 in the Y-direction. The second isolator chip 70V is connected to the first chip 50 and the second chip 60. The second isolator chip 70V is located at a position offset from the center of the second die pad 91 in the X-direction. In the example shown in FIG. 23, the second isolator chip 70V is located closer to the encapsulation side surface 102 than the center of the second die pad 91 is in the X-direction. In this manner, in plain view, the first isolator chip 70U and the second isolator chip 70V are located at positions offset from each other in the X-direction.

The second isolator chip 70V is bonded to the second die pad 91 by the fourth bonding material 114 (refer to FIG. 13). The fourth bonding material 114 bonds the second isolator chip 70V and the second die pad 91 in the same manner as the fourth bonding material 114 bonds the second isolator chip 70Q (refer to FIG. 13) and the second die pad 91 in the second embodiment. The fourth bonding material 114, which bonds the second isolator chip 70V to the second die pad 91, may be a conductive bonding material.

The fourth bonding material 114 may be an insulative bonding material. In this case, the fourth bonding material 114 may be the same insulative bonding material as the third bonding material 113. That is, the third bonding material 113 and the fourth bonding material 114 may have the same relative permittivity. Alternatively, the fourth bonding material 114 may be a different type of insulative bonding material from the third bonding material 113. In an example, the fourth bonding material 114 may be an insulative bonding material having a higher relative permittivity than the third bonding material 113. In other words, the third bonding material 113 may be an insulative bonding material having a lower relative permittivity than the fourth bonding material 114. That is, the third bonding material 113 may have a lower relative permittivity than the fourth bonding material 114.

The electrode pads 73 of the first isolator chip 70U are separately electrically connected to the electrode pads 53 of the first chip 50 by wires W8. The electrode pads 74 of the first isolator chip 70U are separately electrically connected to the electrode pads 63 of the second chip 60 by wires W9.

The electrode pads 73 of the second isolator chip 70V are separately electrically connected to the electrode pads 63 of the second chip 60 by wires W10. The electrode pads 74 of the second isolator chip 70V are separately electrically connected to the electrode pads 53 of the first chip 50 by wire W11.

In the semiconductor device 10 shown in FIG. 23, a first signal received by, for example, the first leads 82 of the first lead frame 80 is input to the first circuit 20 of the first chip 50. Then, the first signal output from the first circuit 20 is input to the second circuit 30 of the second chip 60 through the first coil 41 and the second coil 42 of the transformer 40U of the first isolator chip 70U. The first signal output from the second circuit 30 is output from the semiconductor device 10 through the second leads 92 of the second lead frame 90.

Also, in the semiconductor device 10 shown in FIG. 23, a second signal received by, for example, the second leads 92 of the second lead frame 90 is input to the second circuit 30 of the second chip 60. Then, the second signal output from the second circuit 30 is input to the first circuit 20 of the first chip 50 through the first coil 41 and the second coil 42 of the transformer 40V of the second isolator chip 70V. The second signal output from the first circuit 20 is output from the semiconductor device 10 through the first leads 82 of the first lead frame 80.

In each of the above-described embodiments, the types of the first bonding material 111 and the second bonding material 112 may be changed.

In an example, the first bonding material 111 may be an insulative bonding material, in the same manner as the third bonding material 113. In this case, the first bonding material 111 may be the same insulative bonding material as the third bonding material 113. That is, the third bonding material 113 and the first bonding material 111 may have the same relative permittivity. Alternatively, the first bonding material 111 may be a different type of insulative bonding material from the third bonding material 113. In an example, the first bonding material 111 may be an insulative bonding material having a higher relative permittivity than the third bonding material 113. In other words, the third bonding material 113 may be an insulative bonding material having a lower relative permittivity than the first bonding material 111. That is, the third bonding material 113 may have a lower relative permittivity than the first bonding material 111.

In an example, the second bonding material 112 may be an insulative bonding material, in the same manner as the third bonding material 113. In this case, the second bonding material 112 may be the same insulative bonding material as the third bonding material 113. That is, the third bonding material 113 and the second bonding material 112 may have the same relative permittivity. Alternatively, the second bonding material 112 may be a different type of insulative bonding material from the third bonding material 113. In an example, the second bonding material 112 may be an insulative bonding material having a higher relative permittivity than the third bonding material 113. In other words, the third bonding material 113 may be an insulative bonding material having a lower relative permittivity than the second bonding material 112. That is, the third bonding material 113 may have a lower relative permittivity than the second bonding material 112.

In the second embodiment, the type of the fourth bonding material 114 may be changed.

In an example, the fourth bonding material 114 may be an insulative bonding material, in the same manner as the third bonding material 113. In this case, the fourth bonding material 114 may be the same insulative bonding material as the third bonding material 113. That is, the third bonding material 113 and the fourth bonding material 114 may have the same relative permittivity. Alternatively, the fourth bonding material 114 may be a different type of insulative bonding material from the third bonding material 113. In an example, the fourth bonding material 114 may be an insulative bonding material having a higher relative permittivity than the third bonding material 113. In other words, the third bonding material 113 may be an insulative bonding material having a lower relative permittivity than the fourth bonding material 114. That is, the third bonding material 113 may have a lower relative permittivity than the fourth bonding material 114.

In each of the above-described embodiments, the structure of the isolator chip 70 may be changed. In an example, at least one of the passivation film 78 and the resin layer 79 may be omitted from the isolator chip 70. In a case in which the passivation film 78 is omitted from the isolator chip 70, the third insulating layer 72 and the resin layer 79 serve examples of an “insulator”. In a case in which the resin layer 79 is omitted from the isolator chip 70, the third insulating layer 72 and the passivation film 78 serve as examples of an “insulator”. In a case in which both the passivation film 78 and the resin layer 79 are omitted from the isolator chip 70, the third insulating layer 72 serves as an example of an “insulator”.

The semiconductor device 10 of each of the above-described embodiments is not limited to a digital isolator, and may be applied to, for example, an isolated gate driver, an isolated analog-to-digital converter (ADC), an isolation amplifier, or the like.

Various examples described in this specification may be combined as long as there is no technical contradiction.

In the present disclosure, the term “on” includes the meaning of “above” in addition to the meaning of “on” unless clearly described otherwise in the context. Accordingly, for example, a phrase such as “first element disposed (mounted) on second element” may mean that the first element is directly located (mounted) on the second element in one embodiment and that the first element is located (mounted) above the second element without contacting the second element in another embodiment. Therefore, the term “on” does not exclude a structure in which another element is disposed between the first element and the second element.

The Z-direction as referred to in this disclosure does not have to be the vertical direction, and does not have to exactly coincide with the vertical direction. Accordingly, in the various structures of the present disclosure, “up” and “down” in the Z-direction as referred to in this specification are not limited to “up” and “down” in the vertical direction. For example, the X-direction or the Y-direction may be the vertical direction.

### Clauses

Technical concepts that can be understood from the present disclosure will now be described. Reference characters used in the described embodiment are added to corresponding elements in the clauses to aid understanding without any intention to impose limitations on these elements. The reference characters are given as examples to aid understanding, and are not intended to limit elements to the elements denoted by the reference characters.

### Clause 1

A semiconductor device (10), including:

a first die pad (81) and a second die pad (91) insulated from each other;

a first chip (50) mounted on the first die pad (81);

a second chip (60) mounted on the second die pad (91);

an isolator chip (70) mounted on the first die pad (81) or the second die pad (91) and connected between the first chip (50) and the second chip (60);

a first bonding material (111) disposed between the first die pad (81) and the first chip (50) and bonding the first die pad (81) and the first chip (50);

a second bonding material (112) disposed between the second die pad (91) and the second chip (60) and bonding the second die pad (91) and the second chip (60); and

a third bonding material (113) disposed between the first die pad (81) or the second die pad (91) and the isolator chip (70) and bonding the first die pad (81) or the second die pad (91) and the isolator chip (70), in which

the isolator chip (70) includes

a semiconductor substrate (71),

an insulator (72) disposed on the semiconductor substrate (71), and

an isolation element (40A, 40B) disposed in the insulator (72) and including a first conductive layer (41) and a second conductive layer (42) insulated from each other,

the semiconductor substrate (71) is bonded to the first die pad (81) or the second die pad (91) by the third bonding material (113), and

the third bonding material (113) is an insulative bonding material.

### Clause 2

The semiconductor device according to clause 1, in which the third bonding material (113) is composed of an insulation material having a lower relative permittivity than a semiconductor material of the semiconductor substrate (71).

### Clause 3

The semiconductor device according to clause 2, in which the semiconductor substrate (71) of the isolator chip (70) is a Si substrate.

### Clause 4

The semiconductor device according to clause 2 or 3, in which the third bonding material (113) is composed of an insulation material containing an epoxy resin.

### Clause 5

The semiconductor device according to any one of clauses 1 to 4, in which the third bonding material (113) is composed of an insulation material having a relative permittivity of less than 12.

### Clause 6

The semiconductor device according to any one of clauses 1 to 5, in which a thickness (TC3) of the third bonding material (113) is greater than a thickness (TC1) of the first bonding material (111) and a thickness (TC2) of the second bonding material (112).

### Clause 7

The semiconductor device according to any one of clauses 1 to 6, in which the third bonding material (113) is in contact with the semiconductor substrate (71).

### Clause 8

The semiconductor device according to any one of clauses 1 to 7, in which the third bonding material (113) is one of multiple third bonding materials (113) separated from each other, the multiple third bonding materials (113) each bonding the semiconductor substrate (71) and the first die pad (81) or the second die pad (91).

### Clause 9

The semiconductor device according to any one of clauses 1 to 8, in which

the first chip (50) includes a first semiconductor substrate (51),

the second chip (60) includes a second semiconductor substrate (61),

the first semiconductor substrate (51) is bonded to the first die pad (81) by the first bonding material (111),

the second semiconductor substrate (61) is bonded to the second die pad (91) by the second bonding material (112), and

a thickness (TA3) of the semiconductor substrate (71) of the isolator chip (70) is greater than a thickness (TA1) of the first semiconductor substrate (51) and a thickness (TA2) of the second semiconductor substrate (61).

### Clause 10

The semiconductor device according to any one of clauses 1 to 8, in which

the first chip (50) includes a first semiconductor substrate (51),

the second chip (60) includes a second semiconductor substrate (61), and

a thickness (TA1) of the first semiconductor substrate (51), a thickness (TA2) of the second semiconductor substrate (61), and a thickness (TA3) of the semiconductor substrate (71) of the isolator chip (70) are equal to each other.

### Clause 11

The semiconductor device according to any one of clauses 1 to 10, in which a thickness (TA3) of the semiconductor substrate (71) is greater than 180μm and less than or equal to 400μm.

### Clause 12

The semiconductor device according to any one of clauses 1 to 11, further including:

a first isolator chip (70P), serving as the isolator chip, mounted on the first die pad (81);

a second isolator chip (70Q) mounted on the second die pad (91); and

a fourth bonding material (114) disposed between the second die pad (91) and the second isolator chip (70Q) and bonding the second die pad (91) and the second isolator chip (70Q).

### Clause 13

The semiconductor device according to clause 12, in which a thickness (TC3) of the third bonding material (113) is greater than a thickness (TC4) of the fourth bonding material (114).

### Clause 14

The semiconductor device according to clause 12, in which a thickness (TC3) of the third bonding material (113) is equal to a thickness (TC4) of the fourth bonding material (114).

### Clause 15

The semiconductor device according to any one of clauses 12 to 14, in which the fourth bonding material (114) is a conductive bonding material.

### Clause 16

The semiconductor device according to any one of clauses 1 to 15, in which the first bonding material (111) is a conductive bonding material.

### Clause 17

The semiconductor device according to any one of clauses 1 to 16, in which the second bonding material (112) is a conductive bonding material.

### Clause 18

The semiconductor device according to any one of clauses 1 to 17, in which the first conductive layer (41) and the second conductive layer (42) each include a coil.

### Clause 19

The semiconductor device according to any one of clauses 1 to 17, in which the first conductive layer (151) and the second conductive layer (152) include an electrode plate.

### Clause 20

The semiconductor device according to any one of clauses 1 to 15, in which the first bonding material (111) is an insulative bonding material.

### Clause 21

The semiconductor device according to clause 20, in which the third bonding material (113) has a lower relative permittivity than the first bonding material (111).

### Clause 22

The semiconductor device according to clause 20, in which the third bonding material (113) has a same relative permittivity as the first bonding material (111).

### Clause 23

The semiconductor device according to any one of clauses 1 to 22, in which the second bonding material (112) is an insulative bonding material.

### Clause 24

The semiconductor device according to clause 23, in which the third bonding material (113) has a lower relative permittivity than the second bonding material (112).

### Clause 25

The semiconductor device according to clause 23, in which the third bonding material (113) has a same relative permittivity as the second bonding material (112).

### Clause 26

The semiconductor device according to any one of clauses 1 to 25, further including an encapsulation resin (100) encapsulating the first chip (50), the second chip (60), the first die pad (81), the second die pad (91), the first bonding material (111), the second bonding material (112), and the third bonding material (113).

### Clause 27

The semiconductor device according to clause 26, in which the third bonding material (113) has a lower relative permittivity than the encapsulation resin (100).

### Clause 28

The semiconductor device according to clause 26, in which the third bonding material (113) has a same relative permittivity as the encapsulation resin (100).

Clause 29

The semiconductor device according to any one of clauses 12 to 14, in which the fourth bonding material (114) is an insulative bonding material.

### Clause 30

The semiconductor device according to clause 29, in which the third bonding material (113) has a lower relative permittivity than the fourth bonding material (114).

### Clause 31

The semiconductor device according to clause 29, in which the third bonding material (113) has a same relative permittivity as the fourth bonding material (114).

### Clause 32

The semiconductor device according to any one of clauses 1 to 11, in which the isolator chip (70) is bonded to the first die pad (81) by the third bonding material (113).

### Clause 33

The semiconductor device according to any one of clauses 1 to 11, in which the isolator chip (70) is bonded to the second die pad (91) by the third bonding material (113).

### Clause 34

The semiconductor device according to any one of clauses 1 to 11, further including:

a first isolator chip (70U), serving as the isolator chip, mounted on the first die pad (81); and

a second isolator chip (70V) mounted on the second die pad (91), in which

the first chip (50) includes a first circuit (20),

the second chip (60) includes a second circuit (30),

the first isolator chip (70U) is connected to the first chip (50) and the second chip (60) and is configured to transmit a first signal output from the first circuit (20) to the second circuit (30), and

the second isolator chip (70V) is connected to the first chip (50) and the second chip (60) and is configured to transmit a second signal output from the second circuit (30) to the first circuit (20).

### Clause 35

The semiconductor device according to clause 34, further including a fourth bonding material (114) disposed between the second isolator chip (70V) and the second die pad (91) and bonding the second isolator chip (70V) and the second die pad (91).

### Clause 36

The semiconductor device according to clause 35, in which the fourth bonding material (114) is a conductive bonding material.

### Clause 37

The semiconductor device according to clause 35, in which the fourth bonding material (114) is an insulative bonding material.

### Clause 38

The semiconductor device according to clause 37, in which the third bonding material (113) has a lower relative permittivity than the fourth bonding material (114).

### Clause 39

The semiconductor device according to clause 37, in which the third bonding material (113) has a same relative permittivity as the fourth bonding material (114).

### Clause 40

The semiconductor device according to any one of clauses 34 to 39, in which, as viewed in a thickness-wise direction (Z) of the first die pad (81), the first isolator chip (70U) and the second isolator chip (70V) are located at positions offset from each other in a direction (X) orthogonal to an arrangement direction (Y) of the first die pad (81) and the second die pad (91).

### Clause 41

The semiconductor device according to any one of clauses 34 to 40, in which

the first isolator chip (70U) includes a first isolation element (40U), the first isolation element (40U) including a first conductive layer (41) and a second conductive layer (42) insulated from each other, and

the second isolator chip (70V) includes a second isolation element, the second isolation element including a third conductive layer and a fourth conductive layer insulated from each other.

### Clause 42

The semiconductor device according to any one of clauses 1 to 41, in which the third bonding material (113) is composed of an insulation material having a relative permittivity of less than 4.

The above descriptions are merely exemplary. One skilled in the art would recognize the potential for a wide variety of combinations and substitutions of the elements and methods (manufacturing processes) in addition to those illustrated to describe the techniques of this disclosure. Any substitutions, modifications, and variations within the scope of the claims are intended to be encompassed in the present disclosure.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a first die pad and a second die pad insulated from each other;
a first chip mounted on the first die pad;
a second chip mounted on the second die pad;
an isolator chip mounted on the first die pad or the second die pad and connected between the first chip and the second chip;
a first bonding material disposed between the first die pad and the first chip and bonding the first die pad and the first chip;
a second bonding material disposed between the second die pad and the second chip and bonding the second die pad and the second chip; and
a third bonding material disposed between the first die pad or the second die pad and the isolator chip and bonding the first die pad or the second die pad and the isolator chip, wherein
the isolator chip includes
a semiconductor substrate,
an insulator disposed on the semiconductor substrate, and
an isolation element disposed in the insulator and including a first conductive layer and a second conductive layer insulated from each other,
the semiconductor substrate is bonded to the first die pad or the second die pad by the third bonding material, and
the third bonding material is an insulative bonding material.

2. The semiconductor device according to claim 1, wherein the third bonding material is composed of an insulation material having a lower relative permittivity than a semiconductor material of the semiconductor substrate.

3. The semiconductor device according to claim 2, wherein the semiconductor substrate of the isolator chip is a Si substrate.

4. The semiconductor device according to claim 2, wherein the third bonding material is composed of an insulation material containing an epoxy resin.

5. The semiconductor device according to claim 1, wherein the third bonding material is composed of an insulation material having a relative permittivity of less than 12.

6. The semiconductor device according to claim 1, wherein a thickness of the third bonding material is greater than a thickness of the first bonding material and a thickness of the second bonding material.

7. The semiconductor device according to claim 1, wherein the third bonding material is in contact with the semiconductor substrate.

8. The semiconductor device according to claim 1, wherein the third bonding material is one of multiple third bonding materials separated from each other, the multiple third bonding materials each bonding the semiconductor substrate and the first die pad or the second die pad.

9. The semiconductor device according to claim 1, wherein
the first chip includes a first semiconductor substrate,
the second chip includes a second semiconductor substrate,
the first semiconductor substrate is bonded to the first die pad by the first bonding material,
the second semiconductor substrate is bonded to the second die pad by the second bonding material, and
a thickness of the semiconductor substrate of the isolator chip is greater than a thickness of the first semiconductor substrate and a thickness of the second semiconductor substrate.

10. The semiconductor device according to claim 1, wherein
the first chip includes a first semiconductor substrate,
the second chip includes a second semiconductor substrate, and
a thickness of the first semiconductor substrate, a thickness of the second semiconductor substrate, and a thickness of the semiconductor substrate of the isolator chip are equal to each other.

11. The semiconductor device according to claim 1, wherein a thickness of the semiconductor substrate is greater than 180 μm and less than or equal to 400 μm.

12. The semiconductor device according to claim 1, further comprising:
a first isolator chip, serving as the isolator chip, mounted on the first die pad;
a second isolator chip mounted on the second die pad; and
a fourth bonding material disposed between the second die pad and the second isolator chip and bonding the second die pad and the second isolator chip.

13. The semiconductor device according to claim 12, wherein a thickness of the third bonding material is greater than a thickness of the fourth bonding material.

14. The semiconductor device according to claim 12, wherein a thickness of the third bonding material is equal to a thickness of the fourth bonding material.

15. The semiconductor device according to claim 12, wherein the fourth bonding material is a conductive bonding material.

16. The semiconductor device according to claim 1, wherein the first bonding material is a conductive bonding material.

17. The semiconductor device according to claim 1, wherein the second bonding material is a conductive bonding material.

18. The semiconductor device according to claim 1, wherein the first conductive layer and the second conductive layer each include a coil.

19. The semiconductor device according to claim 1, wherein the first conductive layer and the second conductive layer include an electrode plate.
